(19) United States
(12) Patent Application Publication
(10) Pub. No.: US 2024/0304692 A1
(43) Pub. Date: Sep. 12, 2024

(54) NON-VOLATILE MEMORY DEVICE AND METHOD FOR MANUFACTURING THE SAME

(71) Applicant: IOTMEMORY TECHNOLOGY INC., Taipei City (TW)

(72) Inventors: Der-Tsyr Fan, Taoyuan City (TW); I-Hsin Huang, Taoyuan City (TW); Tzung-Wen Cheng, New Taipei City (TW); Yu-Ming Cheng, Yilan County (TW)

(21) Appl. No.: 18/226,788

(22) Filed: Jul. 27, 2023

Related U.S. Application Data
(60) Provisional application No. 63/451,237, filed on Mar. 10, 2023.

(51) Int. Cl. H01L 29/423; H10B 41/30

(52) U.S. Cl. CPC H01L 29/42328; H10B 41/30

(57) ABSTRACT

A non-volatile memory device includes at least one memory cell, and the memory cell includes a substrate, a select gate, a floating gate, a floating gate cap layer, and an erase gate. The select gate is disposed on the substrate. The floating gate is disposed on the substrate and laterally spaced apart from the select gate, where the floating gate includes top edges forming a closed shape as viewed from a top-down perspective. The floating gate cap layer is disposed on a top surface of the floating gate, where an area of a top surface of the floating gate cap layer is less than an area of a bottom surface of the floating gate. The erase gate is disposed on the floating gate, and one or more of the top edges are covered with the erase gate. A control gate is covered with the erase gate.

### CROSS REFERENCE TO RELATED APPLICATIONS

This application claims the benefit of U.S. Provisional Application No. 63/451,237, filed on Mar. 10, 2023. The content of the application is incorporated herein by reference.

### BACKGROUND OF THE INVENTION

### 1. Field of the Invention

The invention relates to a semiconductor device, and more particularly, to a non-volatile memory device and a method for manufacturing the same.

### 2. Description of the Prior Art

Since a non-volatile memory can, for instance, repeatedly perform operations such as storing, reading, and erasing data, and since stored data is not lost after the non-volatile memory is shut down, the non-volatile memory has been extensively applied in personal computers and electronic equipment.

A conventional structure of non-volatile memory has a stack-gate structure, including a tunneling oxide layer, a floating gate, a coupling dielectric layer, and a control gate disposed on a substrate in order. When a programming or erase operation is performed on such a flash memory device, a suitable voltage is respectively applied to the source region, the drain region, and the control gate, such that electrons are injected into a floating gate, or electrons are pulled out from the floating gate.

In the programming and erase operation of the non-volatile memory, a greater gate-coupling ratio (GCR) between the floating gate and the control gate generally means a lower operating voltage is needed for the operation, and the operating speed and the efficiency of the flash memory are significantly increased as a result. However, during programming or erase operations, electrons have to be injected into or pulled out of the floating gate through a tunneling oxide layer disposed under the floating gate, which often causes damages to the structure of the tunneling oxide layer and thus reduces the reliability of the memory device.

In order to increase the reliability of the memory device, an erase gate is adopted and incorporated into to the memory device, which is capable of pulling the electrons from the floating gate by applying a positive voltage to the erase gate. Thus, since the electrons in the floating gate is pulled out through a tunneling oxide layer disposed on the floating gate rather than through the tunneling oxide layer disposed under the floating gate, the reliability of the memory device is further improved.

With an increasing demand for high-efficient memory devices capable of erasing the stored data more efficiently, there is still a need to provide an improved memory device and a method for manufacturing the same.

### SUMMARY OF THE INVENTION

The invention provides a non-volatile memory device and a method for manufacturing a non-volatile memory device. The non-volatile memory device is capable of erasing the stored data more efficiently.

According to some embodiments of the present disclosure, a non-volatile memory device is disclosed. The non-volatile memory device includes at least one memory cell, and the memory cell includes a substrate, a select gate, a floating gate, a floating gate cap layer, and an erase gate. The select gate is disposed on the substrate. The floating gate is disposed on the substrate and laterally spaced apart from the select gate, where the floating gate includes top edges forming a parallel or closed shape as viewed from a top-down perspective. The floating gate cap layer is disposed on a top surface of the floating gate, where an area of a top view surface of the floating gate cap layer is less than an area of a bottom surface of the floating gate. The erase gate is disposed on the floating gate, and one or more of the top edges are covered with and electrically coupled to the erase gate.

According to some embodiments of the present disclosure, a method for manufacturing a non-volatile memory device includes the following steps. A first conductive layer and a sacrificial layer are formed on a substrate, wherein the conductive layer is disposed between the sacrificial layer and the substrate. Then, at least one through hole or trench (also called strip-shaped through hole) penetrating the first conductive layer and a sacrificial layer is formed. A second conductive layer is filled into the at least one through hole or trench, and then the second conductive layer is etched to form a patterned second conductive layer in the at least one through hole or trench, where the patterned second conductive layer includes at least one top edge. Afterwards, a dielectric cap layer is formed in the at least one through hole or trench to cover a top surface of the patterned second conductive layer. The sacrificial layer is then etched to expose portions of the sidewalls of the patterned second conductive layer. The dielectric cap layer is etched (or pulled-back) until an area of a top surface of the dielectric cap layer is less than an area of a bottom surface of the patterned second conductive layer. As a result, the top edges of the patterned second conductive layer are exposed from the dielectric cap layer.

By using the non-volatile memory device according to the embodiments of the present disclosure, the electrons sorted in the floating gate can be pulled out of the floating gate more efficiently since all or portion of the top edge of the floating gate, which form a closed or parallel shape as viewed from a top-down perspective, can act as a transmission path for the electrons. As a result, the required erase voltage is reduced, and the efficiency of erasing the stored data is improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic top view of a non-volatile memory device according to some embodiments of the present disclosure, where a floating gate is formed in a through hole of a first conductive layer and a sacrificial layer and is made from a second conductive layer.

FIG. 2 is a schematic cross-sectional view of a non-volatile memory device corresponding to line A-A′, line B-B′ and line C-C′ of FIG. 1 according to some embodiments of the present disclosure, where a floating gate includes a recess with curved sidewalls and top tips surrounding the recess.

FIG. 3 is a schematic cross-sectional view of a non-volatile memory device corresponding to line A-A′, line B-B′ and line C-C′ of FIG. 1 according to alternative embodiments of the present disclosure, where a floating gate includes a flat top surface.

FIG. 4 is a schematic cross-sectional view of a non-volatile memory device corresponding to line A-A′, line B-B′ and line C-C′ of FIG. 1 according to alternative embodiments of the present disclosure, where a floating gate cap layer has a reduced height.

FIG. 5 is a schematic top view of a non-volatile memory device according to alternative embodiments of the disclosure, where a strip-shaped second conductive layer is filled in a trench (also called strip-shaped through hole) of a first conductive layer and a sacrificial layer, and is configured to be cut off to form separated floating gates.

FIG. 6 is a schematic cross-sectional view of a non-volatile memory device corresponding to line A-A′, line B-B′ and line C-C′ of FIG. 5 according to some embodiments of the present disclosure, where a floating gate includes a recess with curved sidewalls and opposite top tips.

FIG. 7 is a schematic cross-sectional view of a non-volatile memory device corresponding to line A-A′, line B-B′ and line C-C′ of FIG. 5 according to alternative embodiments of the present disclosure, where a floating gate cap layer has a reduced height.

FIG. 8 to FIG. 22 are schematic diagrams at various stages of manufacture of a method for manufacturing the non-volatile memory device of FIGS. 1 and 2 according to some embodiments of the present disclosure.

FIG. 23 to FIG. 25 are schematic cross-sectional views at various stages of manufacture of a method for manufacturing the non-volatile memory device of FIGS. 1 and 3 according to some embodiments of the present disclosure.

FIG. 26 to FIG. 31 are schematic cross-sectional views at various stages of manufacture of a method for manufacturing the non-volatile memory device of FIGS. 1 and 4 according to some embodiments of the present disclosure.

FIG. 32 to FIG. 34 are schematic cross-sectional views at various stages of manufacture of a method for manufacturing the non-volatile memory device of FIGS. 5 and 6 according to some embodiments of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “under”, “on”, “over”, “above”, “upper”, “bottom”, “top” and the like, may be used herein for ease of description to describe one element or feature's relationship to another element (s) or feature (s) as illustrated in the figures. The spatially relative terms are intended to encompass different orientations of the device in use or operation in addition to the orientation depicted in the figures. For example, if the device in the figures is turned over, elements described as “below” and/or “under” other elements or features would then be oriented “above” and/or “over” the other elements or features. The apparatus may be otherwise oriented (rotated 90 degrees or at other orientations) and the spatially relative descriptors used herein may likewise be interpreted accordingly.

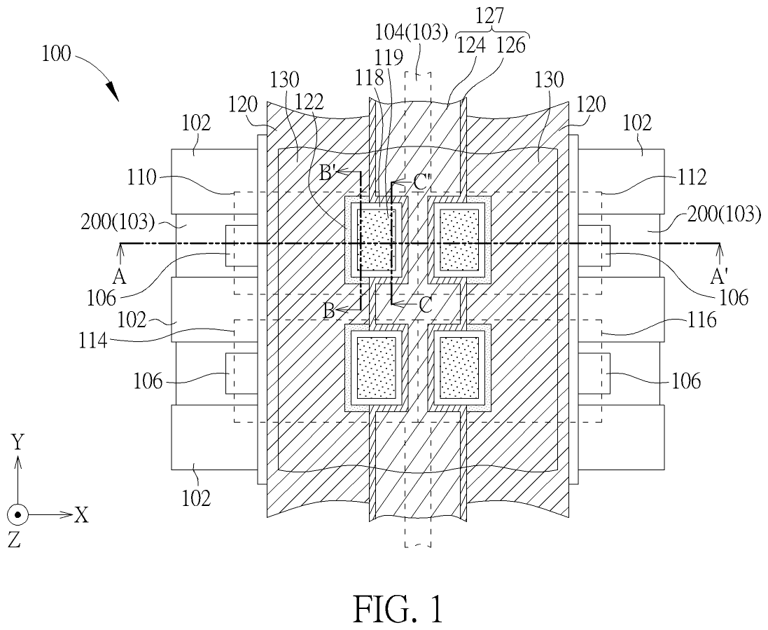

Although the disclosure is described with respect to specific embodiments, the principles of the disclosure, as defined by the claims appended herein, may obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art. FIG. 1 is a schematic top view of a non-volatile memory device according to some embodiments of the present disclosure. Referring to FIG. 1, a non-volatile memory device 100 can be a NOR flash memory device including at least one memory cell, such as four memory cells accommodated in the first, second, third, and fourth memory cell regions 110, 112, 114, and 116, respectively. The structures in the first memory cell region 110 and the second memory cell region 112 have a mirror image of each other, and the structures in the third memory cell region 114 and the fourth memory cell region 116 have a mirror image of each other. According to one embodiment of the present disclosure, the non-volatile memory device 100 includes more than four memory cells, and these memory cells can be arranged in an array with numerous rows and columns.

Referring to FIG. 1, the non-volatile memory device 100 includes a substrate 200 and an isolation structure 102. The substrate 200 can be a semiconductor substrate, such as a silicon substrate, silicon-on-insulator (SOI) substrate, but not limited thereto. The substrate 200 may include at least one epitaxial layer formed on a base substrate. The isolation structure 102 can be made an insulating material such as silicon oxide or silicon oxynitride, and is used to define active areas 103 of the memory cells. The active areas 103 are at an upper portion of the substrate 200.

Each of the memory cells includes a source region 104 and a drain region 106 disposed in the active area 103 defined by the isolation structure 102 and the select gate 120. The source region 104 and the drain region 106 can be doped regions of the same conductivity type, such as n-type or p-type. The conductivity type of the source region 104 and the drain region 106 is different from the conductivity type of the substrate 200, or different from the conductivity type of a doped well (not shown) used to accommodate the source region 104 and the drain region 106. The source region 104 can be disposed at one end of the active area 103 in each memory cell, and the drain region 106 can be arranged at another end of the active area 103 in each memory cell. According to some embodiments of the present disclosure, the source region 104 is common source shared by the memory cells arranged in the same row. For example, the source region 104 can be shared by the memory cells accommodated in the first and second memory cell regions 110, 112, respectively. Besides, the source region 104 can be a continuous region extending along a Y-direction and shared by the memory cells in the same row. Thus, the continuous source region 104 may be regarded as a source line of the non-volatile memory device 100.

Each memory cell can further include a floating gate 118, a floating gate cap layer 119, a select gate 120, a control gate 124, and an erase gate 130.

The floating gates 118 are disposed on the substrate 200. The floating gates 118 are spaced apart from each other and respectively disposed in the first, second, third, and fourth memory cell regions 110, 112, 114, and 116. Each floating gate 118 includes at least one top edge such as four top edges which forms a closed shape as viewed from a top-down perspective (e.g. as viewed along a Z-direction). The floating gates 118 are made of conductive material such as polysilicon or other conductive semiconductor. Because the floating gates 118 are spaced apart from each other, the charges stored in the floating gates 118 would not be directly transmitted between the floating gates 118. In this configuration, each floating gate 118 can be programed or erased independently by coupling the floating gate 118 with an appropriate voltage, thereby determining the state of each memory cell such as state “1” or state “0”.

The floating gate cap layers 119 are respectively disposed on the top surfaces of the floating gates 118. The top surface of each floating gate 118 is partially covered with the floating gate cap layer 119, so the periphery of the top surface of each floating gate 118 is not covered with the floating gate cap layer 119. In other words, the floating gate cap layer 119 does not extend beyond the perimeter of the corresponding floating gate 118. Also, the area of the top surface of the floating gate cap layer 119 is less than the area of the bottom surface of the floating gate 118. The floating gate cap layers 119 are made of insulating material such as silicon nitride, silicon oxynitride or other suitable insulating material. Thus, the conductivity of the floating gate cap layers 119 are much less than the conductivity of the floating gates 118.

A pair of select gates 120 are disposed on the substrate 200 and the isolation structure 102, and each select gate 120 is a continuous structure extending along the Y-direction and passing through the memory cell regions in the same column. For example, one of the select gates 120 can extend along the Y-direction from the first memory cell region 110 to the third memory cell region 114, and another one of the select gates 120 can extend along the Y-direction from the second memory cell region 112 to the fourth memory cell region 116. The select gates 120 can be made of conductive material such as polysilicon, metal or other conductive semiconductor, and each select gate 120 can act as a word line configured to turn on/off the channel regions underneath the select gate 120.

The control gate 124 is disposed in the gap between the select gates 120 and shared by the memory cells arranged in the same row. For example, the control gate 124 can be shared by the memory cells accommodated in the first and second memory cell regions 110, 112, respectively. The control gate 124 can cover the continuous source region 104 and extend along the Y-direction. The control gate 124 is made of conductive material such as polysilicon, metal or other conductive semiconductor. A control gate dielectric layer 126 can be disposed along the sidewalls of the control gate 124, and the control gate dielectric layer 126 and the control gate 124 can constitute a control gate structure 127. When a suitable positive voltage is applied to the control gate 124 of the control gate structure 127, hot carriers (e.g. electrons) flowing in the carrier channel under the floating gate 118 can be injected to and accumulated in the floating gate 118.

The erase gate 130 covers the source region 104, the floating gate cap layers 119, the select gates 130, and the control gate 124, and extends along the Y-direction. In addition, the erase gate 130 covers one or more of the top edges of the floating gate 118 that are not covered with the floating gate cap layer 119. The erase gate 130 is made of conductive material such as polysilicon, metal or other conductive semiconductor. An erase gate dielectric layer (not shown) can be disposed at least between the erase gate 130 and the underneath floating gate 118. Since none of the top edges of the floating gate 118 overlaps the floating gate cap layer 119, when a suitable positive voltage is applied to the erase gate 130, the electrons stored in the floating gate 118 can be transmitted from one or more of the top edges of the floating gate 118 into the erase gate 130 through the erase gate dielectric layer. Thus, the electrons stored in the floating gate 118 can be discharged more efficiently compared with a prior art memory device where electrons are discharged only through one or a pair of linear top edges of a floating gate.

A dielectric spacer 122 made of insulating material can be disposed between the select gate 120 and the corresponding floating gate 118. In some embodiments, a portion of the dielectric spacer 122 can extend along the Y-direction, and another portion of the dielectric spacer 122 can extend along an X-direction. Thus, the dielectric spacer 122 can be disposed on more than one sidewall such as three sidewalls of the floating gate 118.

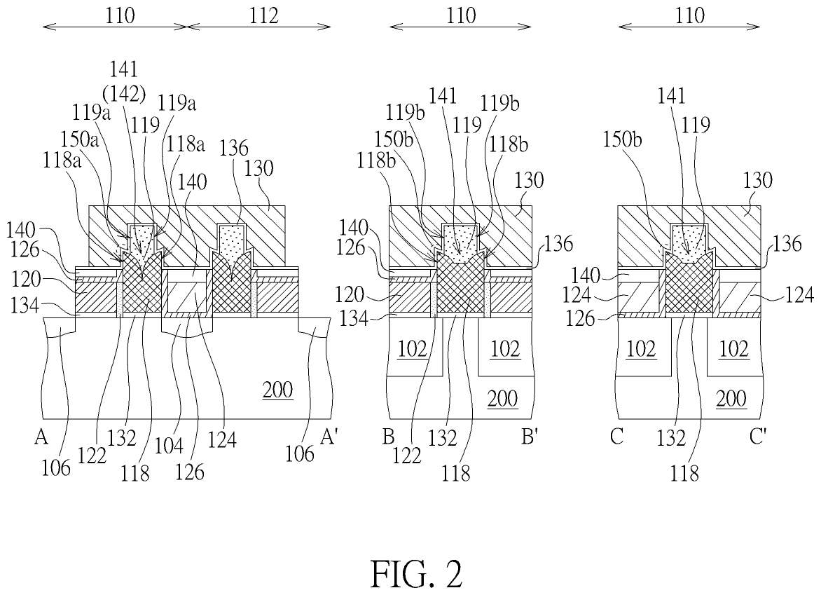

FIG. 2 is a schematic cross-sectional view of a non-volatile memory device corresponding to line A-A′, line B-B′ and line C-C′ of FIG. 1 according to some embodiments of the present disclosure, where a floating gate includes a recess and top tips surrounding the recess. Referring to view AA′ of FIG. 2, the drain regions 106 are disposed in the first memory cell region 110 and the second memory cell region 112, respectively. The source region 104 source region 104 is disposed at the boundary of the first memory cell region 110 and the second memory cell region 112.

For the memory cell in the first memory cell region 110, referring to view AA′ of FIG. 2, the select gate 120 is disposed adjacent to the drain region 106. The select gate dielectric layer 134 is disposed between the substrate 200 and the select gate 120, so the select gate dielectric layer 134 and the select gate 120 can constitute a select gate structure. The dielectric spacer 122 is disposed between the select gate 120 and the floating gate 118 to prevent the occurrence of current leakage between them.

The control gate 124 is disposed over the source region 104, and the control gate 124 is between adjacent floating gates which are respectively disposed in the first memory cell region 110 and the second memory cell region 112. The control gate dielectric layer 126 is disposed between the control gate 124 and the substrate 200, and extends from below the control gate 124 to the sidewalls of the control gate 124. Besides, in some embodiments, the control gate dielectric layer 126 can be disposed on the top surface of the select gate 120.

The floating gate 118 is disposed between the select gate 120 and the control gate 124, and is disposed away from the drain region 106 and adjacent to source region 104. Referring to view AA′, the top surface 141 of the floating gate 118 has a center region 142 lower than the top edges such as first top edges 150a of the floating gate 118. In addition, the top surface 141 of the floating gate 118 includes at least one curved surface which curves smoothly from a substantially vertical orientation to a substantially horizontal orientation along the X-direction (i.e. along the direction from the center region 142 to the first top edges 150a). In view AA′ of FIG. 2, the floating gate 118 includes a pair of top tips respectively connected to opposite first sidewalls 118a of the floating gate 118. In view BB′ of FIG. 2, the top surface 141 of the floating gate 118 includes a flat surface, and further includes another pair of top tips respectively connected to opposite second sidewalls 118b of the floating gate 118. Although the top tips of the floating gate 118 shown in view AA′ and view BB′ of FIG. 2 are laterally spaced apart from each other, the top tips can form a closed shape and surround the center region 142 of the floating gate 118 as viewed from a top-down perspective. In view AA′ and view BB′, the top tips (also the first and second top edges 150a, 150b) of the floating gate 118 are higher than the top surfaces of the select gate 120 and the control gate 124.

Referring to view AA′ of FIG. 2, a floating gate dielectric layer 132 is disposed between the floating gate 118 and the substrate 200. During a programming operation, hot electrons are allowed to pass through the floating gate dielectric layer 132 and accumulate in the floating gate 118.

The floating gate cap layer 119 is disposed on the top surface of the floating gate 118. The lowermost potion of the floating gate cap layer 119 is over the center region 142 of the floating gate 118 and lower than the first top edges 150a of the floating gate 118. Thus, the lowermost potion of the floating gate cap layer 119 can be surrounded by the top tips of the floating gate 118 as viewed from a top-down perspective. The floating gate cap layer 119 includes opposite first sidewalls 119a respectively laterally spaced apart from the first sidewalls 118a of the floating gate 118, and thus the first top edges 150a of the floating gate 118 are not covered with the floating gate cap layer 119.

The erase gate 130 covers the source region 104, the floating gate cap layers 119, the select gates 120, and the control gate 124. An erase gate dielectric layer 136 is disposed at the bottom surface of the erase gate 130, and also covers the source region 104, the floating gate cap layers 119, the select gates 120, and the control gate 124. During an erase operation, referring to view AA′ and view BB′ of FIG. 2, the electrons stored in the floating gate 118 can be discharged to the erase gate 130 through one or more of the first and second top edges 150a, 150b of the floating gate 118.

Referring to view AA′ and BB′ of FIG. 2, an inter-gate dielectric layer 140 is further disposed between the erase gate 130 and other underlying gates such as the select gates 120 and the control gate 124. The inter-gate dielectric layer 140 covers the top surfaces of the select gates 120 and the control gate 124. The inter-gate dielectric layer 140 can also be covered with the erase gate dielectric layer 136. Although the inter-gate dielectric layer 140 is discontinuously disposed on the top surfaces of the select gates 120 and the control gate 124, the inter-gate dielectric layer 140 is a continuous layer extending along the lengthwise direction of the erase gate 130 as viewed from a top-down perspective. Besides, the perimeter of the floating gate 118 can be surrounded by the inter-gate dielectric layer 140 from as viewed a top-down perspective.

Referring to view AA′ and BB′ of FIG. 2, the horizontal position of the top surface of the inter-gate dielectric layer 140 is lower than the first top edges 150a and second top edges 150b of the floating gate 118, and the top surface of the inter-gate dielectric layer 140 can be at substantially the same height even if the heights of the select gates 120 and the control gate 124 are different. In order to reduce the coupling ratio between the erase gate 130 and the floating gate 118, the horizontal position of the top surface of the inter-gate dielectric layer 140 can be properly adjusted to make only the first and second top edges 150a, 150b (see both view AA′ and view BB′ of FIG. 2) and small portions of the sidewalls 118a, 118b (see both view AA′ and view BB′ of FIG. 2) of the floating gate 118 protruded from the inter-gate dielectric layer 140. Thus, the erase voltage required to be applied to the erase gate 130 during the erase operation can be reduced.

Referring to view BB′ of FIG. 2, the floating gate 118 extend beyond the edges of the isolation structure 102. Each sidewall 118b of the floating gate 118 is covered with the select gate 120, the dielectric spacer 122 and the control gate dielectric layer 126. The floating gate cap layer 119 disposed on the floating gate 118 further includes opposite second sidewalls 119b respectively laterally spaced apart from the second sidewalls 118b of the floating gate 118, and thus the second top edges 150b of the floating gate 118 are not covered with the floating gate cap layer 119.

Referring to view CC′ of FIG. 2, each sidewall of the floating gate 118 is covered with the control gate 124 and the control gate dielectric layer 126. The floating gate cap layer 119 disposed on the floating gate 118 further includes opposite sidewalls respectively laterally spaced apart from the sidewalls of the floating gate 118, and thus the second top edges 150b of the floating gate 118 are not covered with the floating gate cap layer 119.

In the following paragraphs, alternative embodiments of the present disclosure are further described, and only the main differences between the embodiments are described for the sake of brevity.

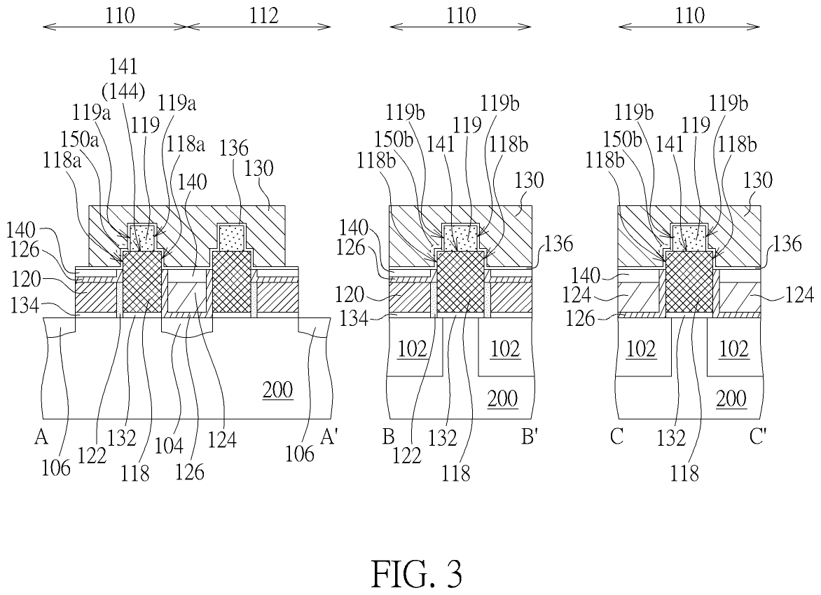

FIG. 3 is a schematic cross-sectional view of a non-volatile memory device corresponding to line A-A′, line B-B′ and line C-C′ of FIG. 1 according to alternative embodiments of the present disclosure, where a floating gate includes a flat top surface. Referring to FIG. 3, especially view AA′ and view BB′ of FIG. 3, the structure shown in FIG. 3 is analogous to the structure shown in FIG. 2, the main difference is that the top surface 141 of the floating gate 118 is a flat surface without the recess shown in FIG. 2. Thus, a center region 144 of the top surface 141 of the floating gate 118 is level with or slightly lower than the first and second top edges 150a, 150b of the floating gate 118. Also, the bottom surface of the floating gate cap layer 119 is level with or slightly lower than the first and second top edges 150a, 150b of the floating gate 118.

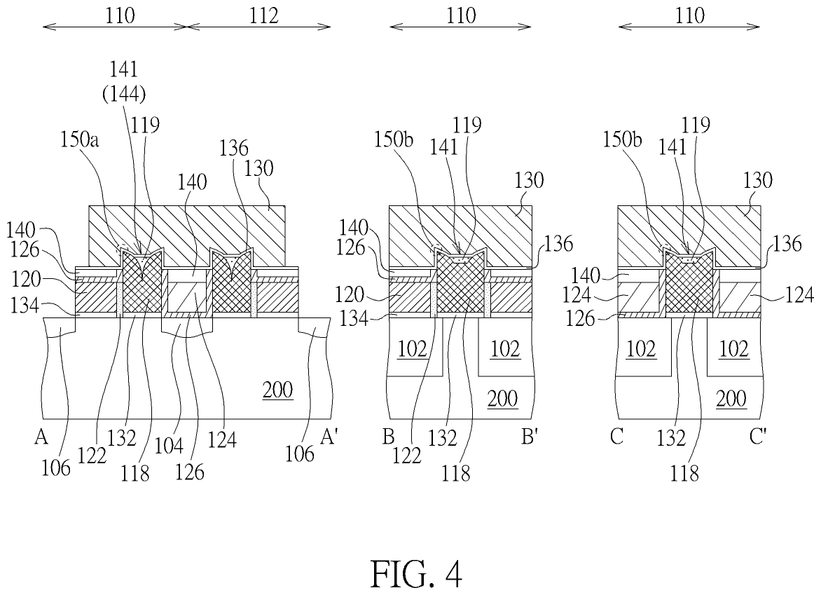

FIG. 4 is a schematic cross-sectional view of a non-volatile memory device corresponding to line A-A′, line B-B′ and line C-C′ of FIG. 1 according to alternative embodiments of the present disclosure, where a floating gate cap layer has a reduced height. Referring to FIG. 4, especially view AA′ and view BB′ of FIG. 4, the structure shown in FIG. 4 is analogous to the structure shown in FIG. 2 where the floating gate cap layer 119 is filled into the recess at the top surface of the floating gate 118. However, the main difference between the structures respectively shown in FIG. 4 and FIG. 2 is that the top surface of the floating gate cap layer 119 in FIG. 2 is lower than the first and second top edges 150a, 150b of the floating gate 118. Also, the erase gate dielectric layer 136 that is disposed directly on the top surface of the floating gate cap layer 119 is lower than the first and second top edges 150a, 150b of the floating gate 118.

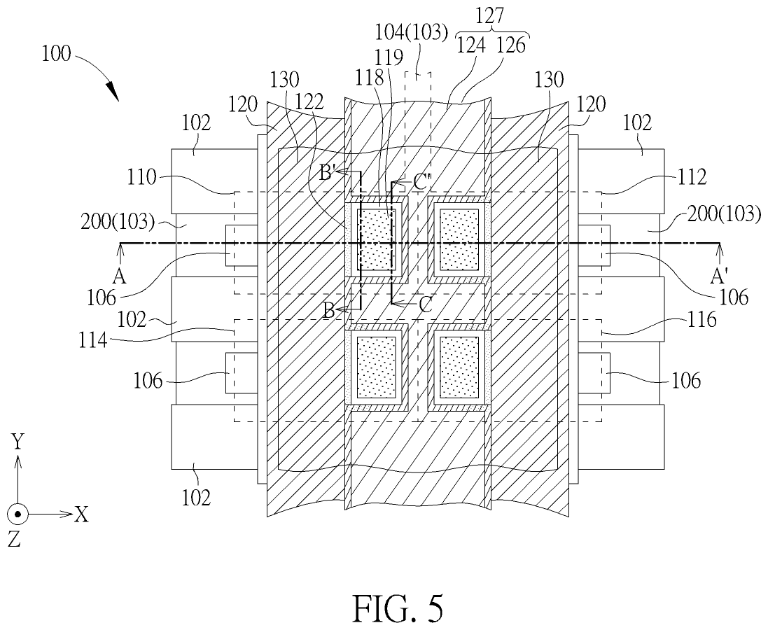

FIG. 5 is a schematic top view of a non-volatile memory device according to alternative embodiments of the present disclosure. The structure shown in FIG. 5 is similar to the structure shown in FIG. 1, the main difference is that the each of the dielectric spacers 122 is linear in shape, so each dielectric spacer 122 cover only one sidewall of each floating gate 118 instead of three sidewalls of each floating gate 118.

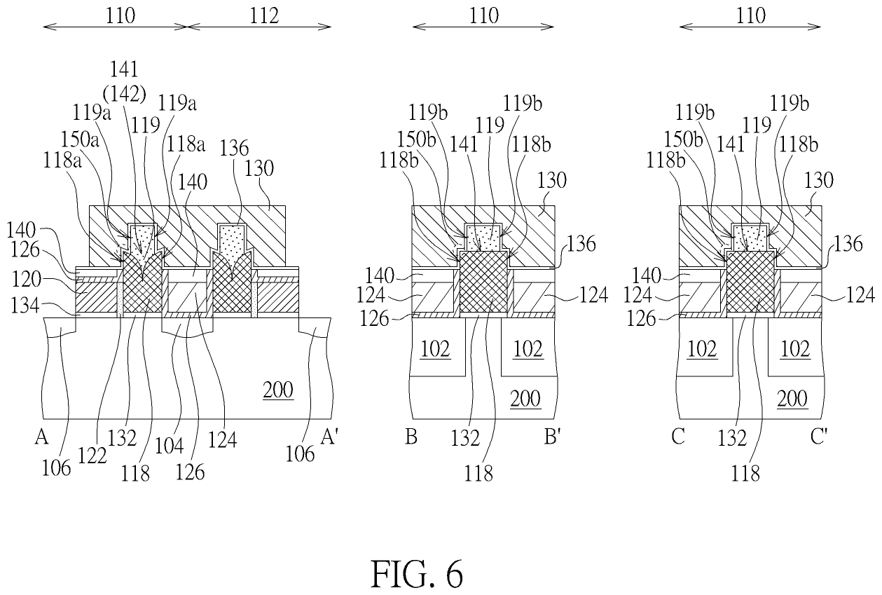

FIG. 6 is a schematic cross-sectional view of a non-volatile memory device corresponding to line A-A′, line B-B′ and line C-C′ of FIG. 5 according to alternative embodiments of the present disclosure. Referring to view AA′ of FIG. 6, the structure in view AA′ of FIG. 6 is identical to the structure shown in view AA′ of FIG. 2. Referring to view BB′ and view CC′ of FIG. 6, however, the top surface 141 of the floating gate 118 is a flat top surface. Also, the bottom surface of the floating gate cap layer 119 is level with the second top edges 150b of the floating gate 118 shown in view BB′ and view CC′ of FIG. 6.

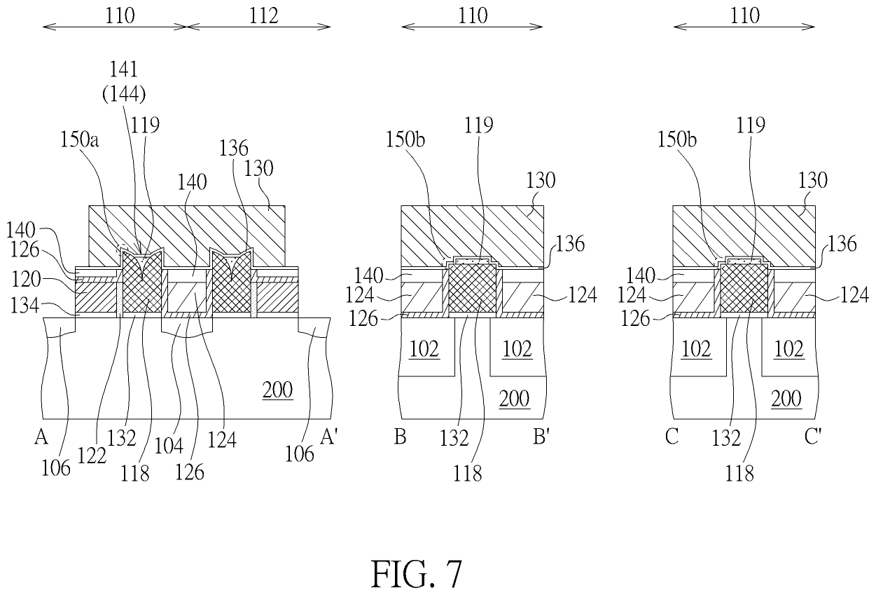

FIG. 7 is a schematic cross-sectional view of a non-volatile memory device corresponding to line A-A′, line B-B′ and line C-C′ of FIG. 5 according to alternative embodiments of the present disclosure. Referring to view AA′ of FIG. 6, the structure in view AA′ of FIG. 7 is identical to the structure shown in view AA′ of FIG. 4. Referring to view BB′ and view CC′ of FIG. 7, however, the top surface of the floating gate 118 is a flat top surface. Also, the bottom surface of the floating gate cap layer 119 is level with the second top edges 150b of the floating gate 118 shown in view BB′ and view CC′ of FIG. 6.

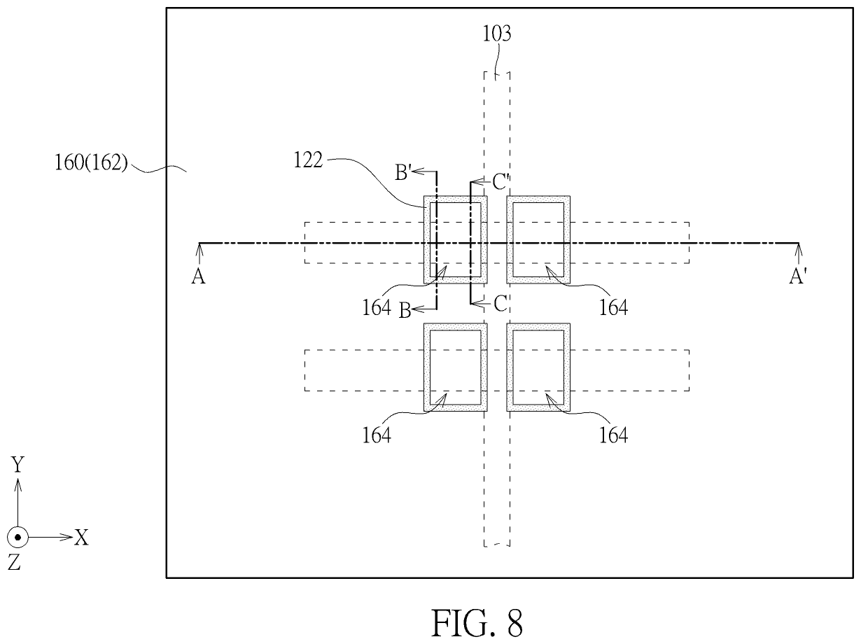

FIG. 8 to FIG. 22 are schematic diagrams at various stages of manufacture of a method for manufacturing the non-volatile memory device of FIGS. 1-2 according to some embodiments of the present disclosure. Referring to FIG. 8, a first conductive layer 160 and a sacrificial layer 162 are formed on a substrate (not shown) to cover an active region 103. The active region 103 can be defined by an isolation structure (not shown) formed in the substrate. The first conductive layer 160 and the sacrificial layer 162 are stacked in sequence from bottom to top, so the first conductive layer 160 is disposed between the substrate (also the active region) and the sacrificial layer 162. The first conductive layer 160 is made of conductive material such as polysilicon, metal or other conductive semiconductor. The sacrificial layer 162 is made of insulating material such as silicon nitride, silicon oxynitride or other suitable insulating material.

Then, referring to FIG. 8, a patterning process is performed on the stacked structure including the first conductive layer 160 and the sacrificial layer 162 to form at least one through hole such as four through holes 164 in the stacked structure. Each of the through holes 164 can penetrate the first conductive layer 160 and the sacrificial layer 162. The through holes 164 are disposed according to the positions of branches of the active region 103. For example, the dimension of the through hole 164 along the Y-direction can be greater than the dimension of the underlying active region 103 along the same direction (i.e. Y-direction). Besides, the through hole 164 can extend beyond the opposite edges of the active region 103.

Afterwards, a dielectric spacer 122 is formed on the sidewalls of each of the through holes 164, and each dielectric spacer 122 forms a closed shape as viewed from a top-down perspective (e.g. along the Z-direction). The dielectric spacer 122 is a single-layered or multi-layered structure, and is made of insulating material such as silicon nitride, silicon oxynitride or other suitable insulating material.

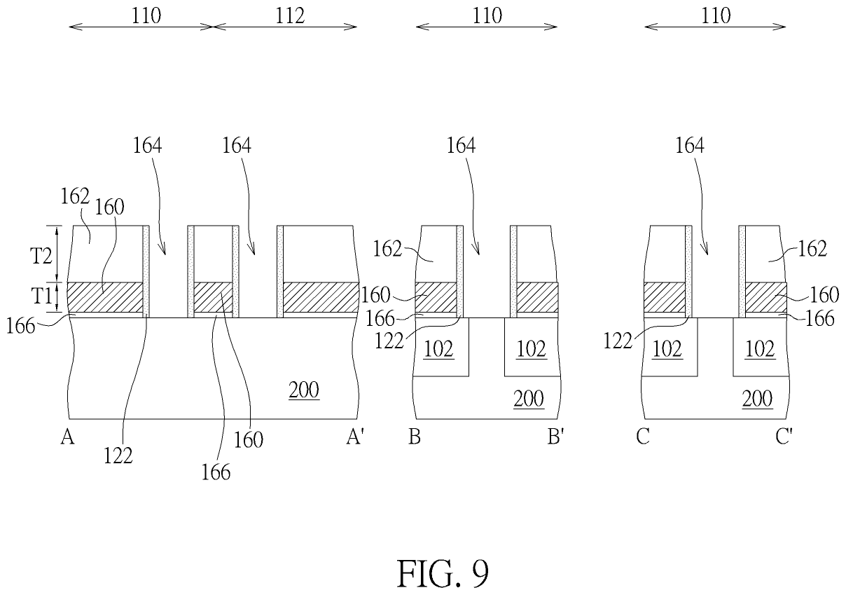

FIG. 9 is a schematic cross-sectional view corresponding to line A-A′, line B-B′ and line C-C′ of FIG. 8 according to some embodiments of the present disclosure. Referring to view AA′ of FIG. 9, a thin dielectric layer 166, which can form a select gate dielectric layer in the following processes, the first conductive layer 160, and the sacrificial layer 162 are disposed on the substrate 200 in sequence. The thickness T1 of the first conductive layer 160 can be the same or less than the thickness T2 of the sacrificial layer 160.

Referring to view BB′ and view CC′, the dielectric spacer 122 is disposed on the isolation structure 102, and the dielectric spacer 122 does not extend beyond the vertical edge of the isolation structure 102. In other words, each through hole 164 can extend laterally beyond the vertical opposite edges of the isolation structure 102.

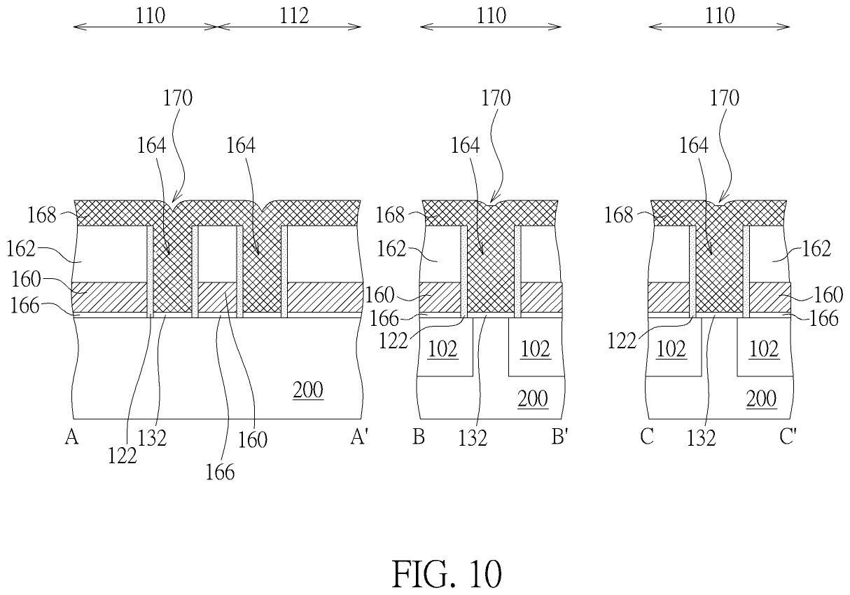

FIG. 10 is a schematic cross-sectional view at a manufacturing stage subsequent to FIG. 9 according to some embodiments of the present disclosure. Referring to view AA′ of FIG. 10, a floating gate dielectric layer 132 is formed at the bottom of the through hole 164 to cover the substrate 200, and then a second conductive layer 168 is formed on the sacrificial layer 162 and filled into the through holes 164 by a deposition process. By properly adjusting the thickness of the second conductive layer 168, the top surface of the second conductive layer 168 directly over the through hole 164 can have a recess 170 with curved lateral surfaces. The contour of the recess 170 can be affected by the thickness of the second conductive layer 168. When the thickness of the second conductive layer 168 is less than half the width of the through hole 164, the recess 170 would have vertical lateral surfaces instead of curved lateral surfaces. When the thickness of the second conductive layer 168 is more than twice the width of the through hole 164, the second conductive layer 168 would have a relatively flat top surface without any recess 170.

Referring to view BB′ and view CC′ of FIG. 10, the recess 170 in views BB′ and view CC′ exhibits curved lateral surfaces and a flat bottom surface and is directly disposed over the through hole 164. Thus, as viewed from the top-down perspective, the curved lateral surfaces of each recess 170 can form a closed shape and do not extend beyond any sidewalls of each through hole 164.

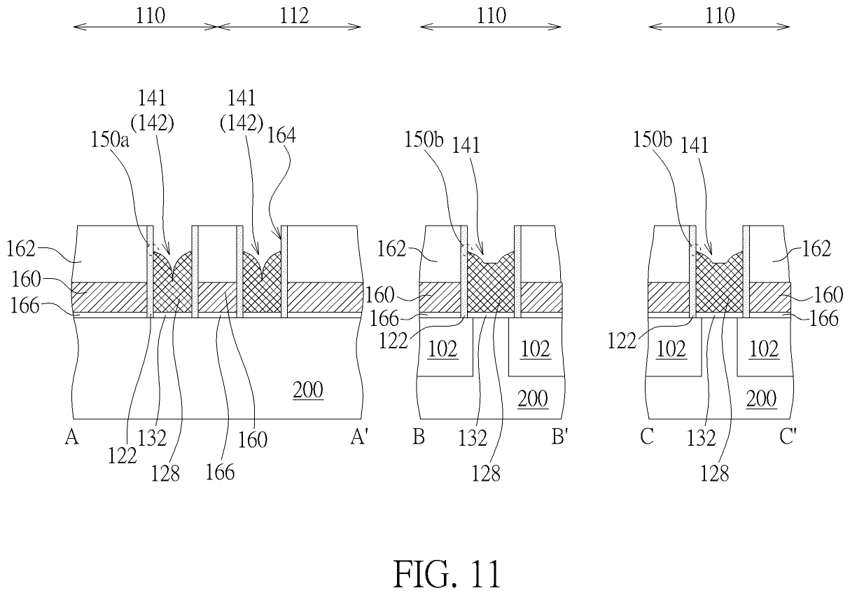

Afterwards, an etching process is performed on the second conductive layer 168 so as to obtain the structure shown in FIG. 11.

FIG. 11 is a schematic cross-sectional view at a manufacturing stage subsequent to FIG. 10 according to some embodiments of the present disclosure. Referring to view AA′ of FIG. 11, by performing the etching back process on the second conductive layer, a patterned second conductive layer 128 is formed in the through hole 164. The patterned second conductive layer 128 can function as a floating gate in a subsequently formed non-volatile memory device. The top surface 141 of the patterned second conductive layer 128 includes a center region 142 which is lower than at least one first top edge 150a of the patterned second conductive layer 128. The center region 142 of the top surface of the patterned second conductive layer 128 is lower than the top surface of the sacrificial layer 162, and higher than the top surface of the first conductive layer 160. At this stage of manufacture, the patterned second conductive layer 128 includes at least one curved surface which curves smoothly from a substantially vertical orientation to a substantially horizontal orientation along the direction from the center region 142 to the first top edge 150a. Also, in view AA′ of FIG. 11, the patterned second conductive layer 128 includes a pair of top tips respectively including opposite first top edges 150a of the patterned second conductive layer 128.

Referring to view BB′ and view CC′ of FIG. 11, the top surface 141 of the patterned second conductive layer 128 also includes a flat or slightly inclined surface which is lower than at least one second top edge 150b of the patterned second conductive layer 128. Thus, the first and second top edges 150a, 150b of the patterned second conductive layer 128 in each through hole 164 can form a closed shape as viewed from the top-down perspective.

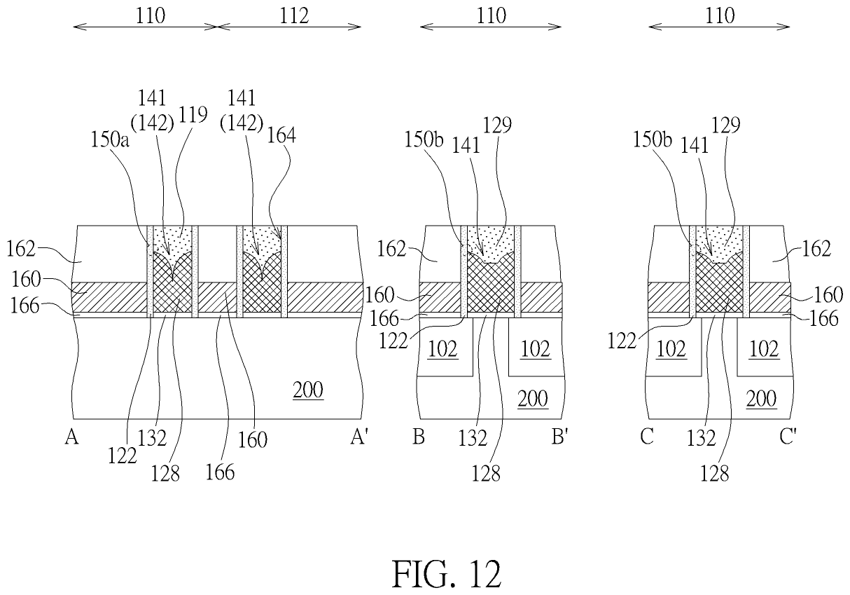

FIG. 12 is a schematic cross-sectional view at a manufacturing stage subsequent to FIG. 11 according to some embodiments of the present disclosure. Referring to view AA′ of FIG. 12, a dielectric cap layer 129 is filled into the through hole 164 and covers the top surface of the patterned second conductive layer 128. The dielectric cap layer 129 can be formed by depositing a dielectric layer (not shown) on the sacrificial layer 162 and in the through hole 164, and then the dielectric layer is planarized until most of the dielectric layer disposed outside the through hole 164 is removed.

Referring to view BB′ and view CC′ of FIG. 12, the dielectric cap layer 129 is also filled into the through hole 164 and covers the top surface of the patterned second conductive layer 128.

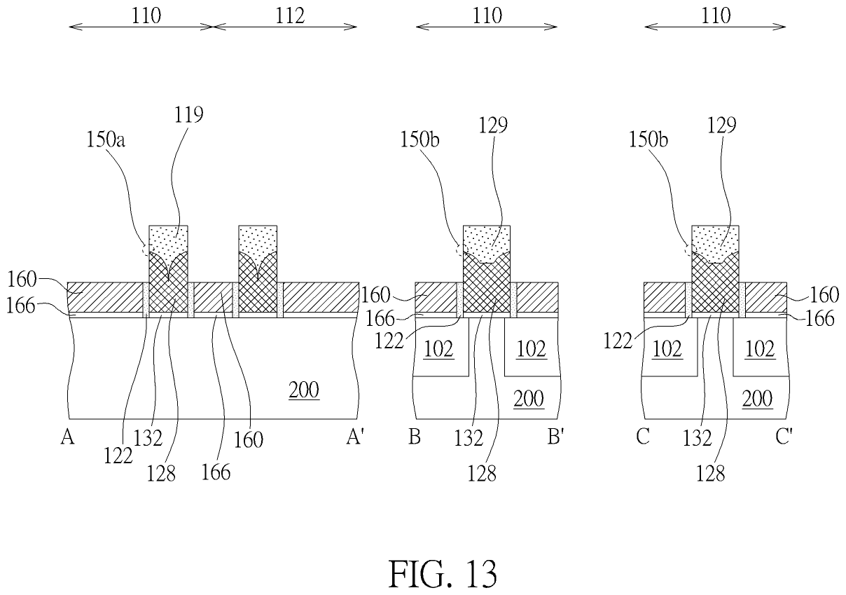

Afterwards, the sacrificial layer 162 is removed to obtain the structure shown in FIG. 13.

FIG. 13 is a schematic cross-sectional view at a manufacturing stage subsequent to FIG. 12 according to some embodiments of the present disclosure. Referring to view AA′ of FIG. 10, the sacrificial layer 162 shown in FIG. 12 is removed to thereby expose the top surface of the first conductive layer 160. At this stage of manufacture, upper portions of the opposite sidewalls of the patterned second conductive layer 128 can be exposed, and all of the opposite sidewalls of the dielectric cap layer 129 also can be exposed.

Referring to view BB′ and view CC′ of FIG. 13, upper portions of the opposite sidewalls of the patterned second conductive layer 128 are exposed, and all the opposite sidewalls of the dielectric cap layer 129 are also exposed.

Afterwards, the first conductive layer 160 and the dielectric spacer 122 are patterned to obtain the structure shown in FIG. 13.

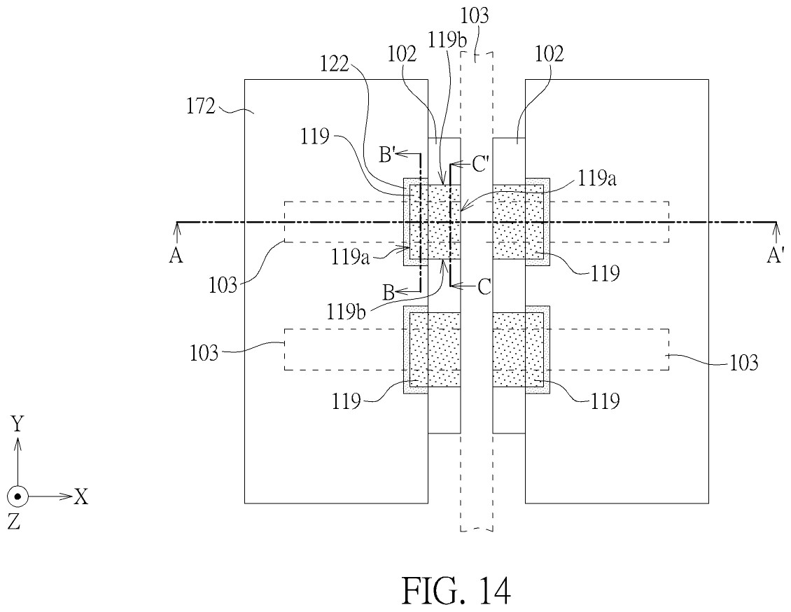

FIG. 14 is a schematic top view at a manufacturing stage subsequent to FIG. 13 according to some embodiments of the present disclosure. Referring to FIG. 14, by using an etch mask 172, the patterning process is performed to remove a portion of the first conductive layer 160 between the floating gates (not shown) and the floating gate cap layers 119. Thus, one of the sidewalls 119a of the dielectric cap layer 129 can be exposed. Opposite sidewalls 119b of the dielectric cap layer 129 can be partially exposed and partially covered with the patterned dielectric spacer 122.

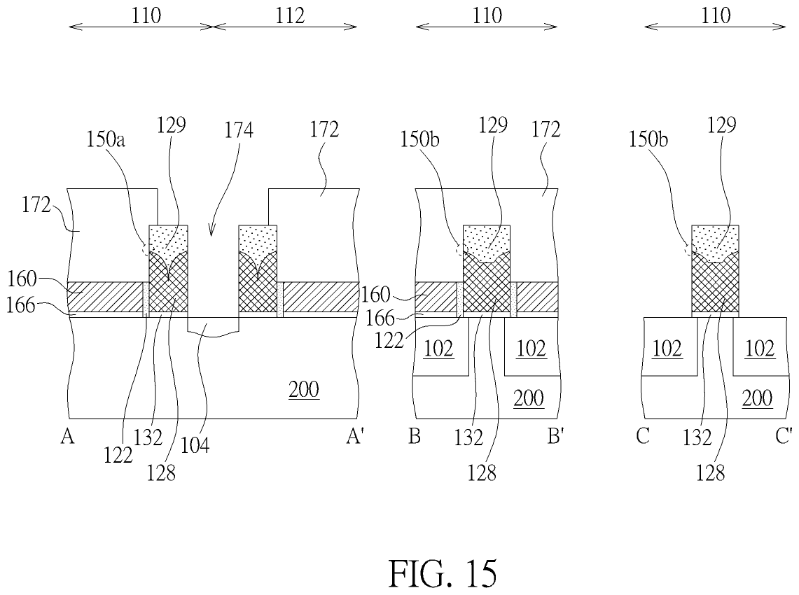

FIG. 15 is a schematic cross-sectional view corresponding to line A-A′, line B-B′ and line C-C′ of FIG. 14 according to some embodiments of the present disclosure. Referring to view AA′ of FIG. 12, the etch mask 172 includes an opening 174 through which the floating gate cap layer 118 is partially exposed. An ion implantation process is performed to form a source region 104 in the substrate 200 between the floating gates 118. Thus, the etch mask 172 can also act as a mask in the ion implantation process.

Referring to view BB′ of FIG. 15, the top surface of the dielectric cap layer 129 is covered with the etch mask 172.

Referring to view CC′ of FIG. 15, the opposite sidewalls of the patterned second conductive layer 128 are fully exposed and not covered with the etch mask 172.

Afterwards, the etch mask 172 is removed to expose the top surface of the first conductive layer 160.

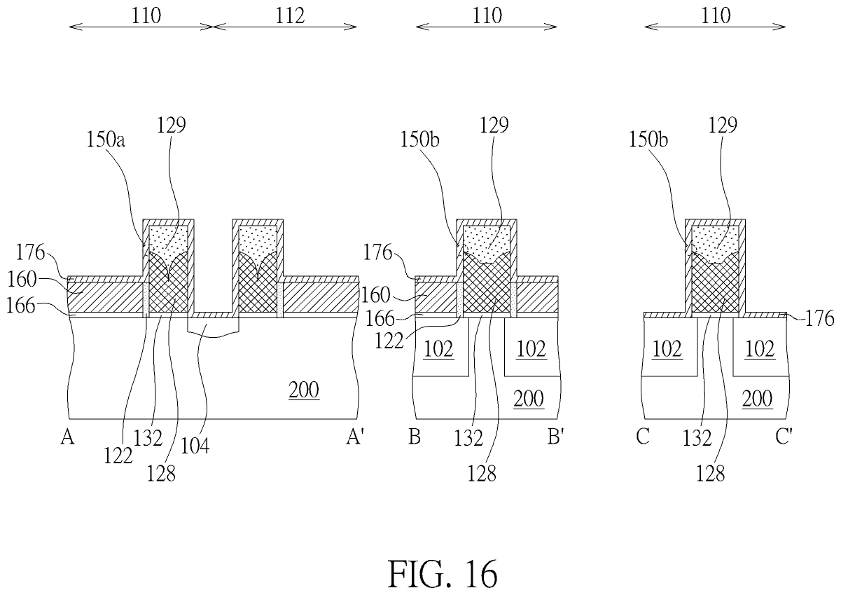

FIG. 16 is a schematic cross-sectional view at a manufacturing stage subsequent to FIG. 15 according to some embodiments of the present disclosure. Referring to view AA′ of FIG. 13, a control gate dielectric layer 176 is deposited to conformally cover the underlying components such as the first conductive layer 160, the opposite sidewalls of the patterned second conductive layer 128, the top surface of the dielectric cap layer 129 and the substrate 200. The control gate dielectric layer 176 can be a composite dielectric layer including silicon oxide/silicon nitride/silicon oxide, but not limited thereto.

Referring to view CC′ of FIG. 16, the top surface of the isolation structure 102 is also covered with the control gate dielectric layer 176.

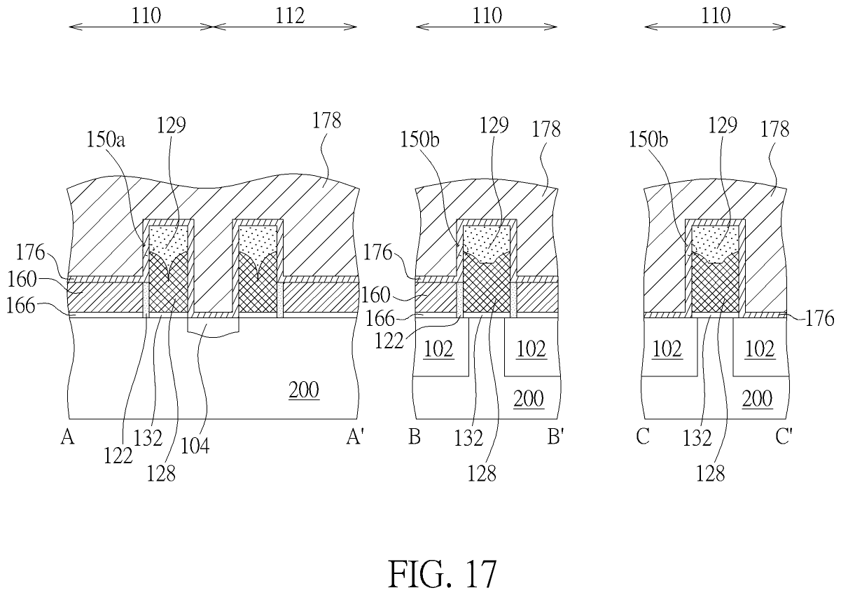

FIG. 17 is a schematic cross-sectional view at a manufacturing stage subsequent to FIG. 16 according to some embodiments of the present disclosure. Referring to view AA′ of FIG. 17, a third conductive layer 178 is disposed on the substrate 200 to cover the dielectric cap layer 129 and the first conductive layer 160. The gap between the floating gates 118 can also be filled with the third conductive layer 178. The third conductive layer 178 is made of conductive material such as polysilicon, metal or other conductive semiconductor.

Referring to view CC′ of FIG. 17, the opposite sidewalls can be fully covered with third conductive layer 178.

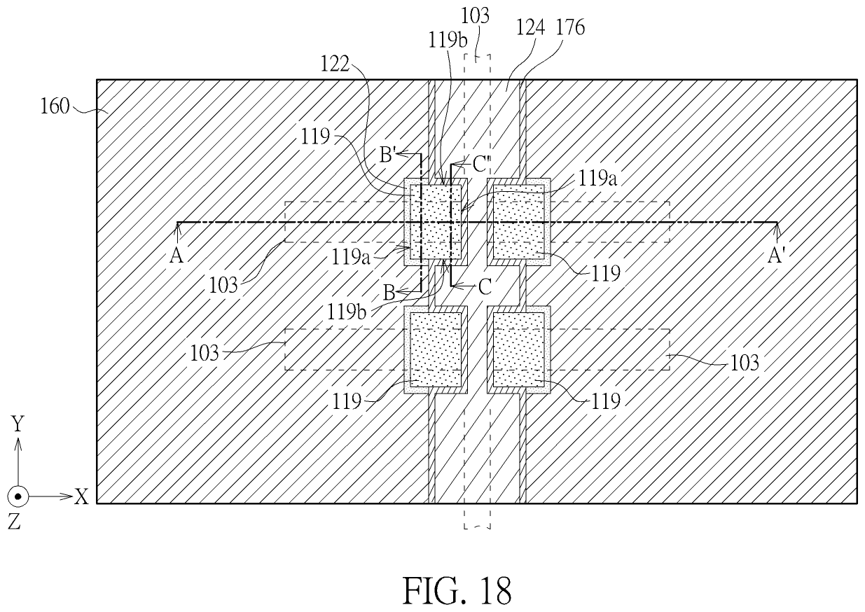

Afterwards, referring to view AA′ and view BB′ of FIG. 17, the third conductive layer 178 can be further planarized and etched back to a predetermined depth until the top surface of the third conductive layer 178 is lower than the first and second top edges 150a, 150b of the patterned second conductive layer 128. Thus, the structure shown in FIG. 18 can be obtained.

FIG. 18 is a schematic top view at a manufacturing stage subsequent to FIG. 17 according to some embodiments of the present disclosure. Referring to FIG. 18, after etching back the third conductive layer 178, a control gate 124 extending along the Y-direction can be obtained. A pair of control gate dielectric layers 176 also extend along the Y-direction respectively, so the control gate 124 and the floating gates 118 can be separated by the control gate dielectric layers 176. Besides, the control gate 124 and the first conductive layer 160 can be separated by the control gate dielectric layers 176.

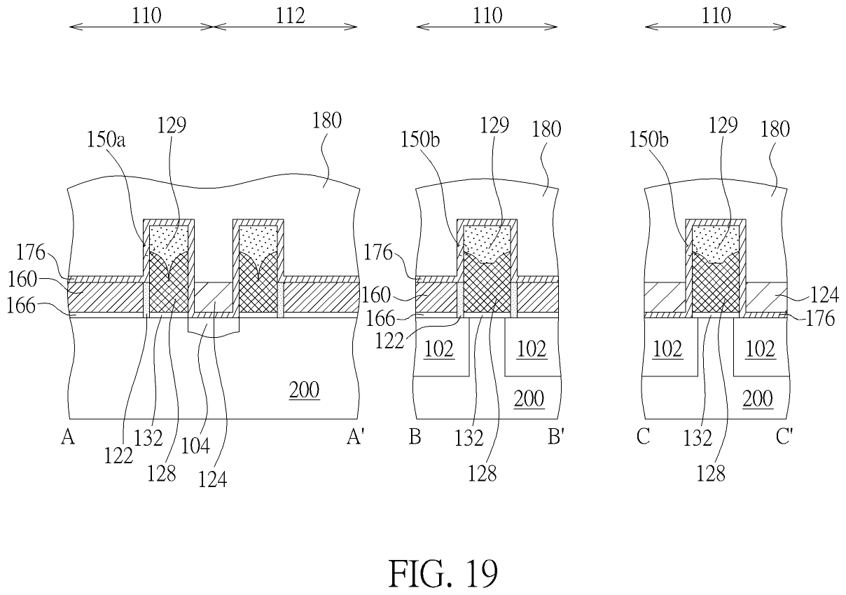

FIG. 19 is a schematic cross-sectional view at a manufacturing stage subsequent to FIG. 18 according to some embodiments of the present disclosure. Referring to FIG. 15, the top surface of the control gate 124 is lower than the first top edges 150a of the patterned second conductive layer 128. Then, a filling dielectric layer 180 is disposed on the substrate 200 to cover the dielectric cap layer 129, the first conductive layer 160 and the control gate 124. The composition of the filling dielectric layer 180 can be different from the composition of the control gate dielectric layer 176 according to different requirements.

Referring to view CC′ of FIG. 18, the control gate 124 is formed at two opposite sidewalls of the patterned second conductive layer 128, and the top surface of the control gate 124 is lower than the second top edges 150b of the patterned second conductive layer 128.

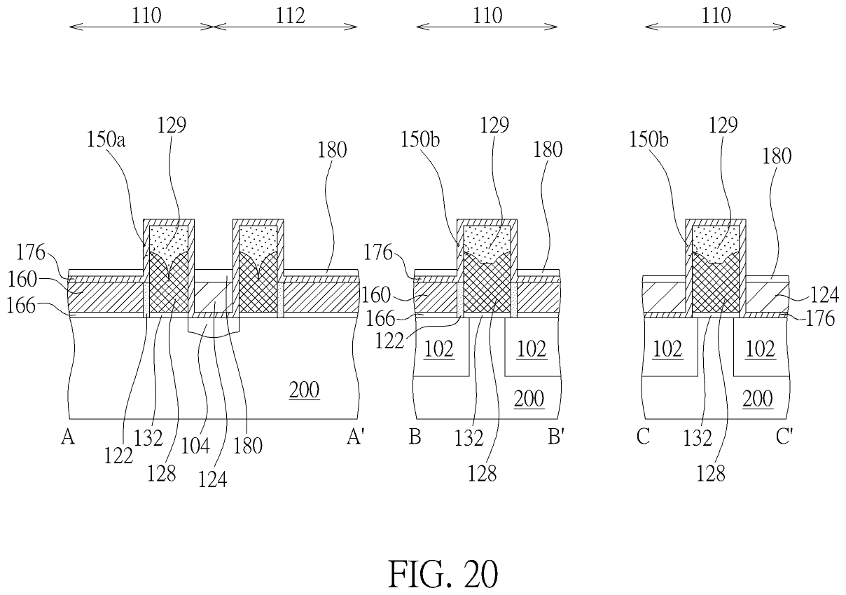

Afterwards, referring to view AA′ and view BB′ of FIG. 19, the filling dielectric layer 180 can be further planarized and etched back to a predetermined depth until the top surface of the filling dielectric layer 180 is lower than the first and second top edges 150a, 150b of the patterned second conductive layer 128. Thus, the structure shown in FIG. 20 can be obtained.

FIG. 20 is a schematic cross-sectional view at a manufacturing stage subsequent to FIG. 19 according to some embodiments of the present disclosure. Referring to FIG. 20, by etching the top surface of the filling dielectric layer 180 down to a predetermined depth, the overlapping area between a subsequently formed erase gate (now shown) and the sidewall of the patterned second conductive layer 128 can be adjusted accordingly. The filling dielectric layer 180 can be regarded as an inter-gate dielectric layer since the filling dielectric layer 180 is used to be disposed between the erase gate and the control gate 124 in the subsequent process. When the horizontal position of the top surface of the filling dielectric layer 180 becomes closer to, but keeps lower than, the first and second top edges 150a, 150b of the patterned second conductive layer 128, the overlapping area between the erase gate and the sidewall of the patterned second conductive layer 128 can become smaller. Thus, the coupling ratio between the erase gate and the patterned second conductive layer 128 can be reduced by adjusting the horizontal position of the top surface of the filling dielectric layer 180.

Besides, although the filling dielectric layer 180 shown in FIG. 20 looks like discontinuous layers separated from each other, the filling dielectric layer 180 is a continuous layer surrounding the patterned second conductive layer 128 and the dielectric cap layer 129 as viewed from a top-down perspective.

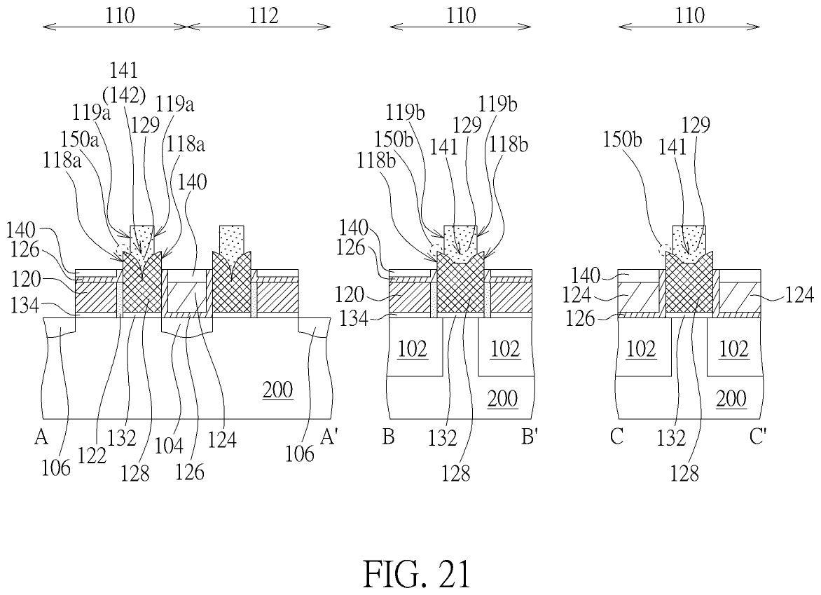

FIG. 21 is a schematic cross-sectional view at a manufacturing stage subsequent to FIG. 20 according to some embodiments of the present disclosure. Referring to FIG. 21, especially view AA′ and view BB′ of FIG. 21, an etching process such as a wet etching process is performed to remove the exposed control gate dielectric layer 126 that originally covers the sidewalls 119a, 119b of the dielectric cap layer 129 and originally covers the first and second top edges 150a, 150b of the patterned second conductive layer 128. In this way, upper portions of the sidewalls 118a, 118b of the patterned second conductive layer 128 can be exposed from the control gate dielectric layer 126. Besides, during the same etching process, the dielectric cap layer 129 can also be laterally etched (also called pull back) until the area of the top surface of the dielectric cap layer 129 is less than the area of the bottom surface of the floating gate 119, and thus the top tips (also first and second top edges 150a, 150b) of the patterned second conductive layer 128 are exposed. An inter-gate dielectric layer 140, which is formed from the filling dielectric layer 180 shown in FIG. 20, has a top surface lower than the first and second top edges 150a, 150b of the patterned second conductive layer 128. Once the manufacturing stage shown in FIG. 21 is complete, the dielectric cap layer 129 can be regarded as the floating gate cap layer 119 shown in FIG. 2, and the patterned second conductive layer 128 can be regarded as the floating gate 118 shown in FIG. 2.

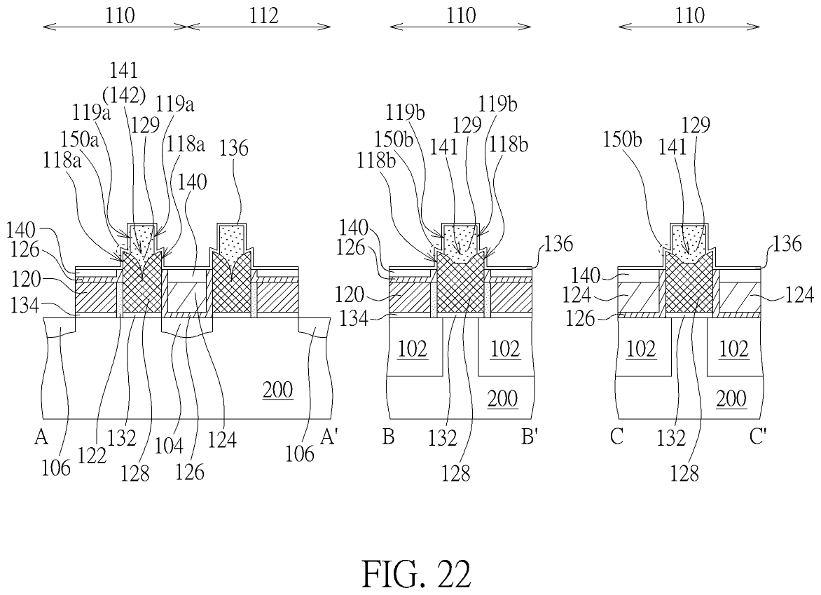

FIG. 22 is a schematic cross-sectional view at a manufacturing stage subsequent to FIG. 21 according to some embodiments of the present disclosure. Referring to view AA′ of FIG. 22, the first conductive layer can be patterned to become a select gate 120. Afterwards, at least one drain region such as two drain regions 106 is formed at sides of the select gates 120. The drain regions 106 are disposed in the first memory cell region 110 and the second memory cell region 112, respectively, which can be electrically coupled to each other through vias or contacts in the subsequent manufacturing processes. The dopants and the doping concentrations of the source region 104 and the drain region 106 can be the same or different.

Afterwards, referring to both view AA′ and view BB′, an erase gate dielectric layer 136 is conformally formed to cover the top tips (also top edges 150a, 150b) of the patterned second conductive layer 128, the peripheral region the patterned second conductive layer 128, and the upper portions of the sidewalls 118a, 118b of the patterned second conductive layer 128. The erase gate dielectric layer 136 also covers the top surface of the inter-gate dielectric layer 140.

Afterwards, the erase gate and other components may be formed so as to obtain a non-volatile memory device similar to the structure shown in FIGS. 1 and 3.

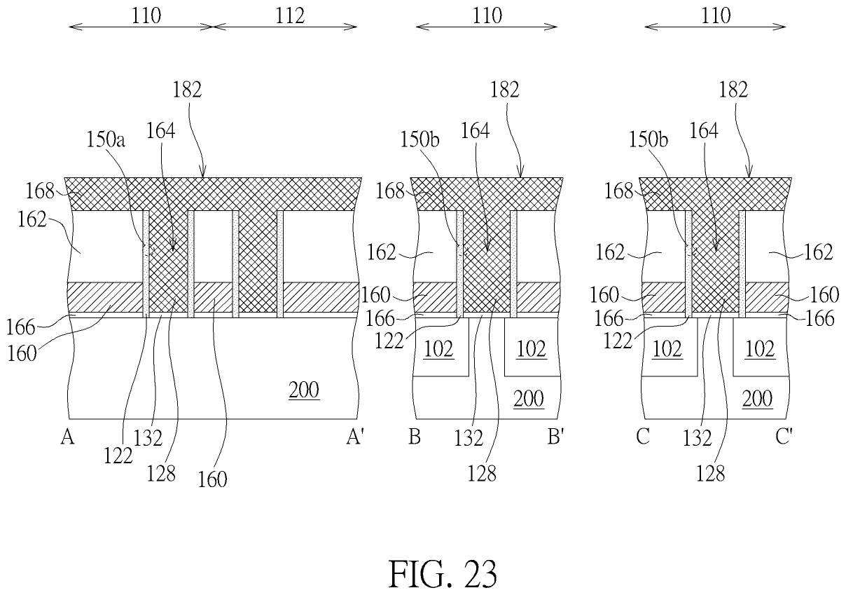

FIG. 23 to FIG. 25 are schematic cross-sectional views at various stages of manufacture of a method for manufacturing the non-volatile memory device of FIG. 3 according to some embodiments of the present disclosure. In FIG. 23 to FIG. 25, view AA′, view BB′ and view CC′ correspond to the line A-A′, line B-B′, and line C-C′ of FIG. 1, respectively. Besides, since the manufacturing processes of the embodiments shown in FIG. 23 to FIG. 25 are similar to the manufacturing processes of the embodiments shown in FIG. 8 to FIG. 22, only the main differences between the embodiments are described for the sake of brevity.

Referring to view AA′, view BB′ and view CC′ of FIG. 23, the structure formed at this manufacturing stage is similar to the structure shown in FIG. 10, the main difference is that the top surface of the second conductive layer 168 disposed over the through hole 164 is a flat surface 182 without any recess as shown in FIG. 10.

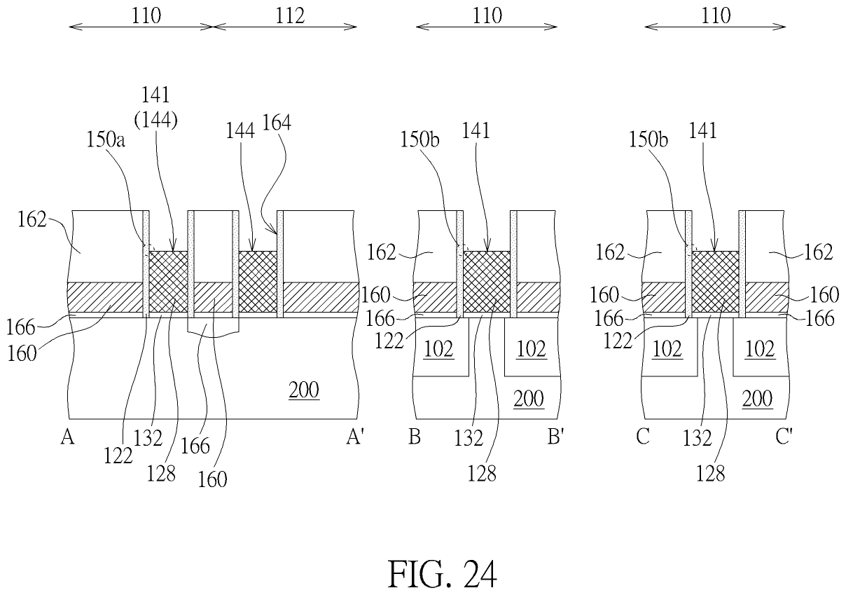

FIG. 24 is a schematic cross-sectional view at a manufacturing stage subsequent to FIG. 23 according to some embodiments of the present disclosure. Referring to FIG. 24, especially view AA′ and view BB′, by performing an etching back process on the second conductive layer, a patterned second conductive layer 128 is formed in the through hole 164. The structure formed at this manufacturing stage is similar to the structure shown in FIG. 11, the main difference is that the top surface 141 of the patterned second conductive layer 128 is a flat surface without any recess. Thus, a center region 144 of the top surface of the patterned second conductive layer 128 is substantially level with first and second top edges 150a, 150b of the patterned second conductive layer 128.

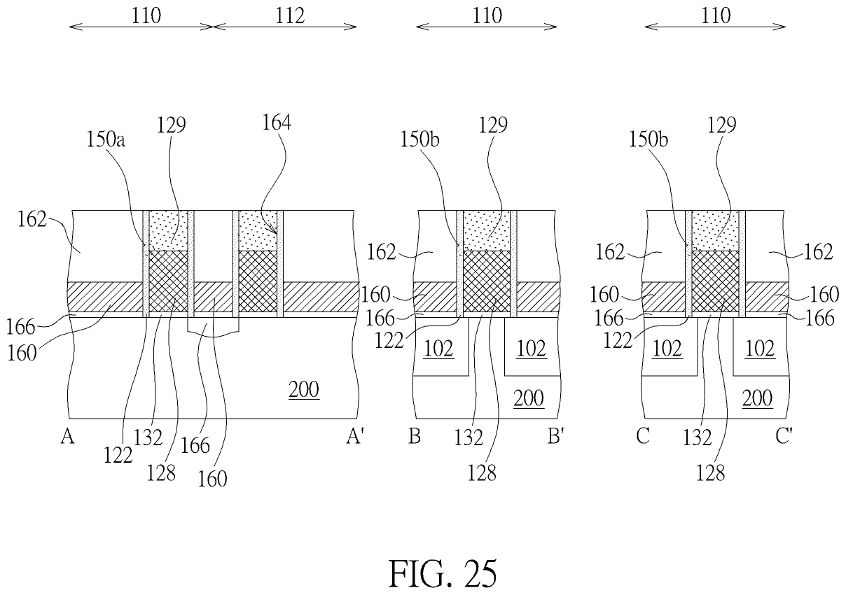

FIG. 25 is a schematic cross-sectional view at a manufacturing stage subsequent to FIG. 24 according to some embodiments of the present disclosure. Referring to FIG. 25, a dielectric cap layer 129129 is filled into the through hole 164 and covers the top surface of the patterned second conductive layer 128. The bottom surface of the dielectric cap layer 129 is a flat surface without any structures protruding downward from the bottom of the dielectric cap layer 129.

Afterwards, the manufacturing processes similar to those described in FIGS. 13-22 and other manufacturing processes can be performed to obtain a non-volatile memory device similar to the structure shown in FIGS. 1 and 3.

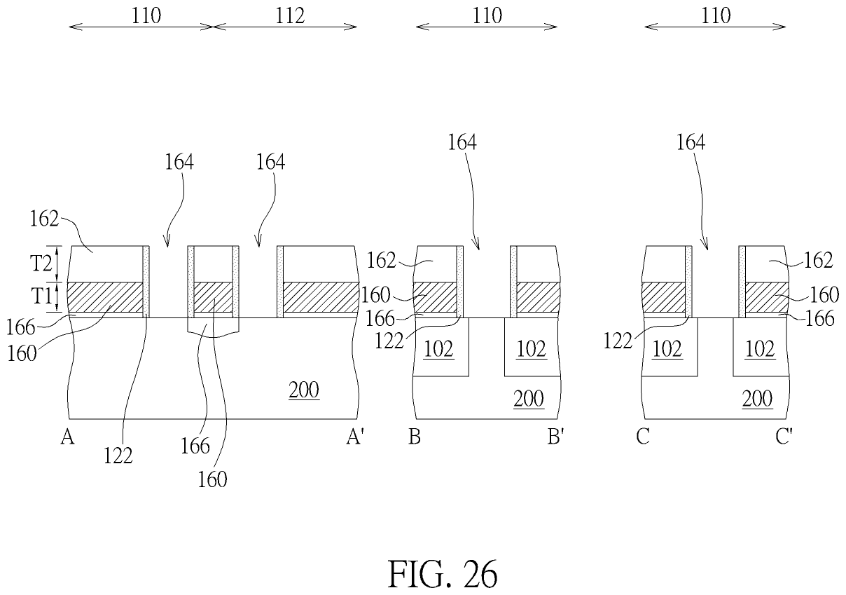

FIG. 26 to FIG. 31 are schematic cross-sectional views at various stages of manufacture of a method for manufacturing the non-volatile memory device of FIGS. 1 and 4 according to some embodiments of the present disclosure. In FIG. 26 to FIG. 31, view AA′, view BB′ and view CC′ correspond to the line A-A′, line B-B′, and line C-C′ of FIG. 1, respectively. Besides, since the manufacturing processes of the embodiments shown in FIG. 26 to FIG. 31 are similar to the manufacturing processes of the embodiments shown in FIG. 8 to FIG. 22, only the main differences between the embodiments are described for the sake of brevity.

Referring to view AA′, view BB′ and view CC′ of FIG. 26, the structure formed at this manufacturing stage is similar to the structure shown in FIG. 9, the main difference is that the thickness T1 of the first conductive layer 160 is substantially equal to or greater than the thickness T2 of the sacrificial layer 162.

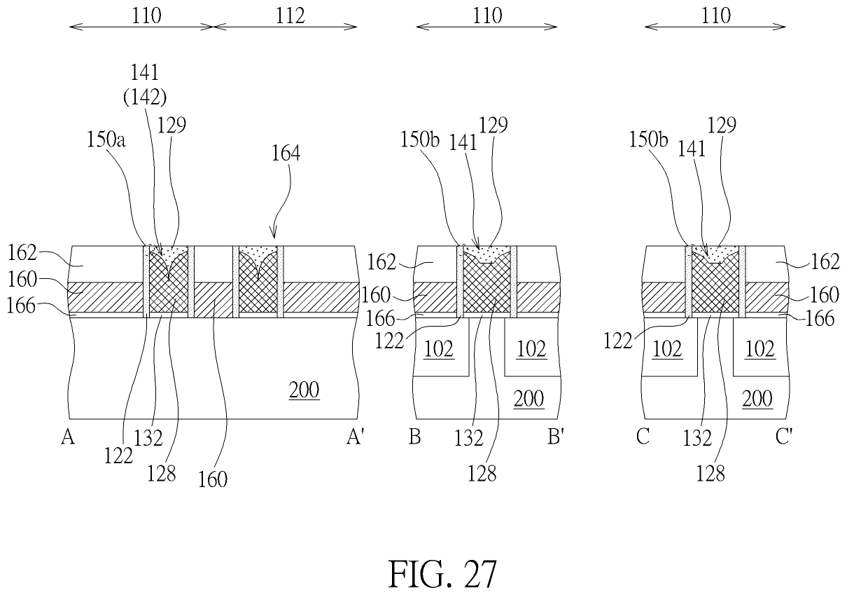

FIG. 27 is a schematic cross-sectional view at a manufacturing stage subsequent to FIG. 26 according to some embodiments of the present disclosure. Referring to FIG. 27, a patterned second conductive layer 128 and a dielectric cap layer 129 are formed in the through hole 164, and the dielectric cap layer 129 covers the top surface 141 of the patterned second conductive layer 128. The structure formed at this manufacturing stage is similar to the structure shown in FIG. 12, the main difference is that the vertical distance between the top surface of the dielectric cap layer 129 and the first and second top edges 150a, 150b of the patterned second conductive layer 128 is much less than that shown in FIG. 12. In some embodiments, the distance between the top surface of the dielectric cap layer 129 and the first and second top edges 150a, 150b of the patterned second conductive layer 128 is less than one sixth of the vertical distance between the bottom surface and the first and second top edges 150a, 150b of the patterned second conductive layer 128.

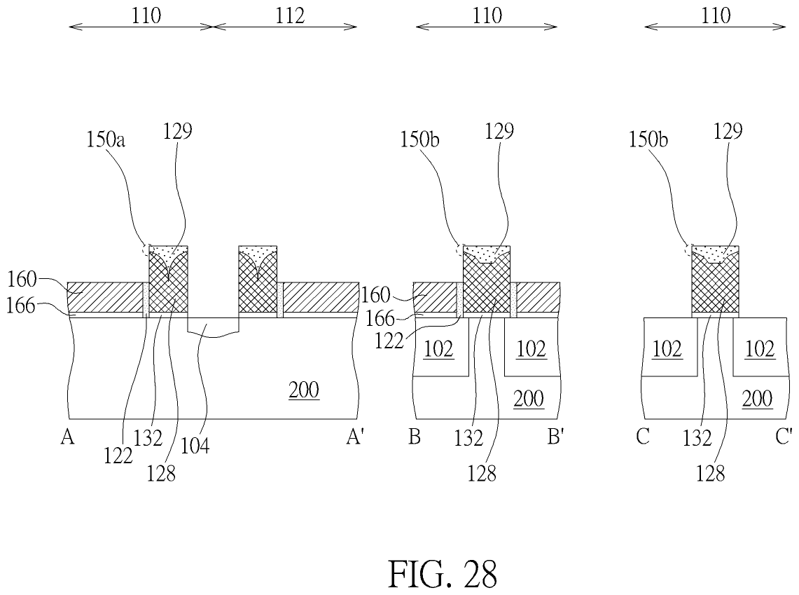

FIG. 28 is a schematic cross-sectional view at a manufacturing stage subsequent to FIG. 27 according to some embodiments of the present disclosure. The structure formed at this manufacturing stage is similar to the structure shown in FIG. 12.

Referring to view AA′ of FIG. 28, the sacrificial layer is removed completely, and the first conductive layer 160 originally between the adjacent floating gates 118 is also removed. A source region 104 is formed in the substrate 200 between the floating gates 118.

Referring to view CC′ of FIG. 28, the opposite sidewalls of the patterned second conductive layer 128 are fully exposed and not covered with the first conductive layer 160.

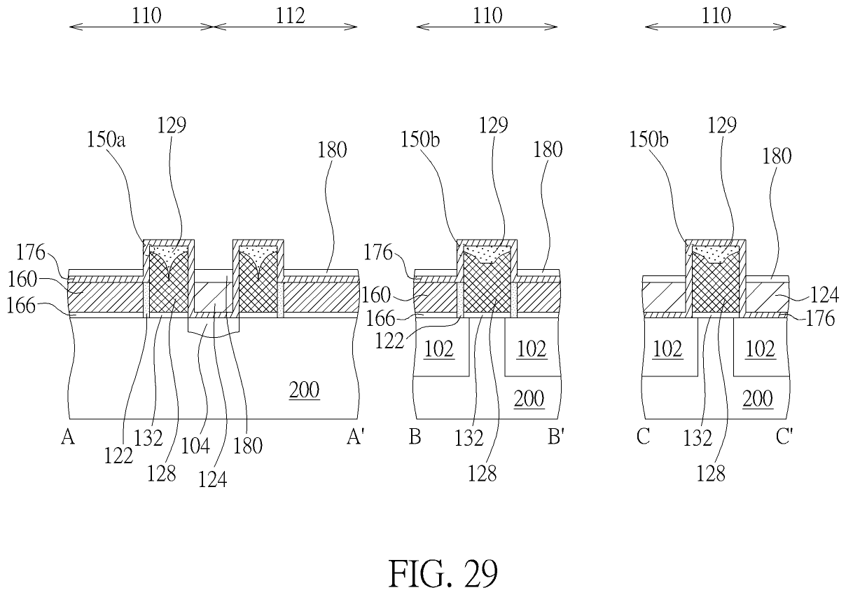

FIG. 29 is a schematic cross-sectional view at a manufacturing stage subsequent to FIG. 28 according to some embodiments of the present disclosure. The structure formed at this manufacturing stage is similar to the structure shown in FIG. 20.

Referring to view AA′ of FIG. 29, the control gate 124 is formed between the adjacent floating gates 118, and the filling dielectric layer 180 is formed to cover the top surfaces of the first conductive layer 160 and the control gate 124. Besides, the top surface of the dielectric cap layer 129 is higher than the top surface of the filling dielectric layer 180.

Referring to view CC′ of FIG. 29, the opposite sidewalls of the patterned second conductive layer 128 are partially covered with the control gate 124, and the filling dielectric layer 180 covers the top surface of the control gate 124.

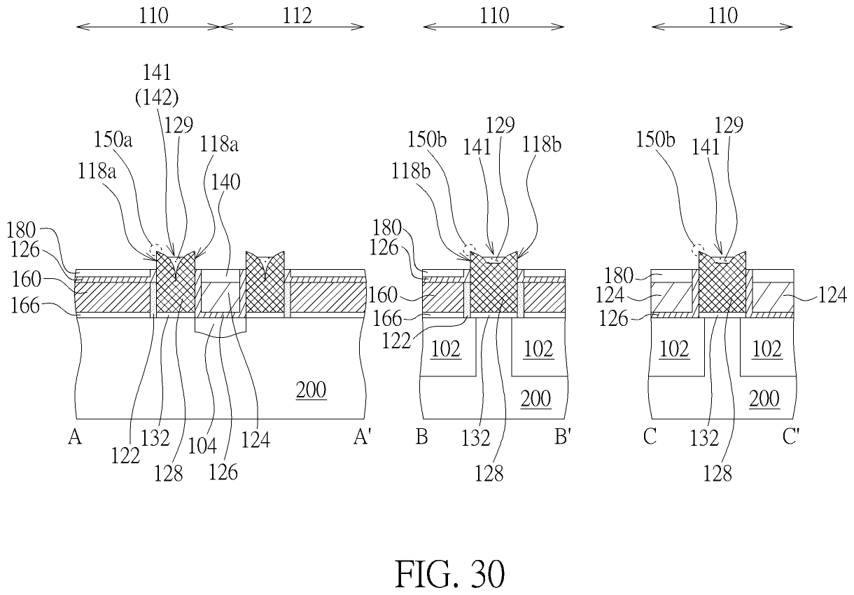

FIG. 30 is a schematic cross-sectional view at a manufacturing stage subsequent to FIG. 29 according to some embodiments of the present disclosure. The structure formed at this manufacturing stage is similar to the structure shown in FIG. 21.

Referring to FIG. 30, especially view AA′ and view BB′ of FIG. 30, an etching process such as a wet etching process is performed to remove the control gate dielectric layer 126 that originally covers the sidewalls 119a, 119b of the dielectric cap layer 129 and originally covers the first and second top edges 150a, 150b of the patterned second conductive layer 128. In this way, upper portions of the sidewalls 118a, 118b of the patterned second conductive layer 128 can be exposed from the control gate dielectric layer 126. Besides, during the same etching process, the dielectric cap layer 129 can also be vertically and laterally etched until the top surface of the dielectric cap layer 129 is lower than the first and second top edges 150a, 150b of the patterned second conductive layer 128.

In order to reduce the coupling ratio between the patterned second conductive layer 128, which can function as a floating gate, and a subsequently formed erase gate 130, the horizontal position of the top surface of the dielectric cap layer 129 is properly etched to make only the first and second top edges 150a, 150b and small portions of the top surface of the patterned second conductive layer 128 exposed from the dielectric cap layer 129 (see both view AA′ and view BB′ of FIG. 30). Besides, the top surface of the dielectric cap layer 129 is higher than the top surface of an inter-gate dielectric layer 140, which is formed from the filling dielectric layer 180 shown in FIG. 29. Once the manufacturing stage shown in FIG. 30 is complete, the dielectric cap layer 129 can be regarded as the floating gate cap layer 119 shown in FIG. 4, and the patterned second conductive layer 128 can be regarded as the floating gate 118 shown in FIG. 4.

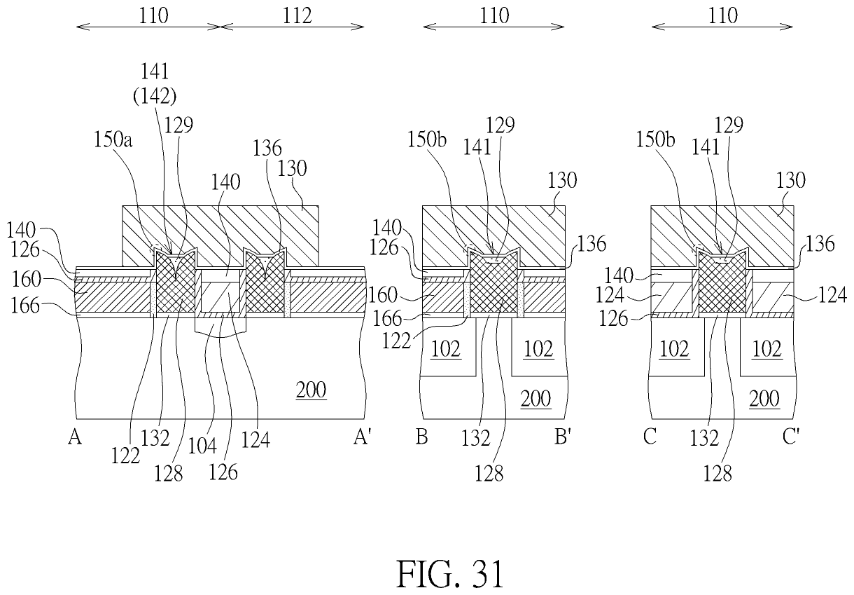

FIG. 31 is a schematic cross-sectional view at a manufacturing stage subsequent to FIG. 30 according to some embodiments of the present disclosure. The structure formed at this manufacturing stage is similar to the structure shown in FIG. 4.

Referring to both view AA′ and view BB′, an erase gate dielectric layer 136 is conformally formed to cover the top tips (also first and second top edges 150a, 150b) of the patterned second conductive layer 128, the peripheral region of the top surface of the patterned second conductive layer 128, and the upper portions of the sidewalls of the patterned second conductive layer 128. The erase gate dielectric layer 136 also covers the top surface of the inter-gate dielectric layer 140. Then, an erase gate 130 is formed to cover the first conductive layer 160, the patterned second conductive layer 128, the dielectric cap layer 129, and the control gate 124.

Afterwards, the first conductive layer 160 can be further patterned to obtain a select gate (not shown), a drain region (not shown) can be further formed by an ion implantation process, and other components can also be formed so as to obtain a non-volatile memory device similar to the structure shown in FIGS. 1 and 4.

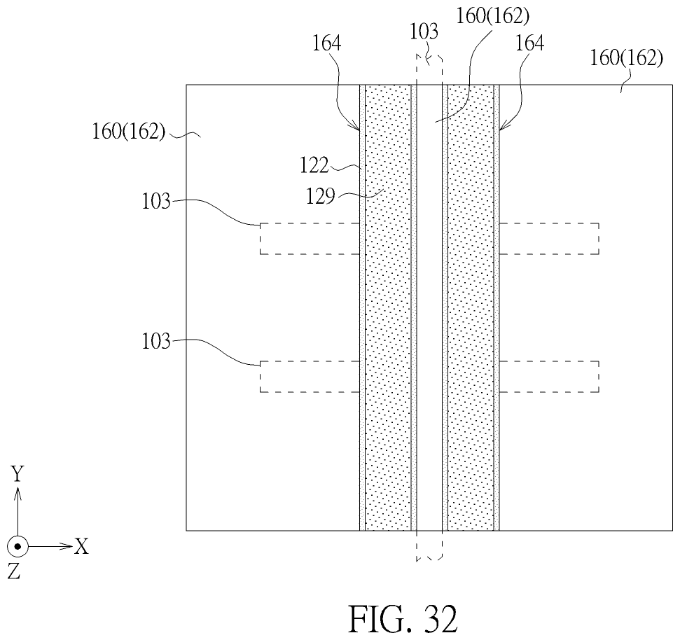

FIG. 32 to FIG. 34 are schematic cross-sectional views at various stages of manufacture of a method for manufacturing the non-volatile memory device of FIGS. 5 and 6 according to some embodiments of the present disclosure. In FIG. 32 to FIG. 34, view AA′, view BB′ and view CC′ correspond to the line A-A′, line B-B′, and line C-C′ of FIG. 5, respectively. Besides, since the manufacturing processes of the embodiments shown in FIG. 32 to FIG. 34 are similar to the manufacturing processes of the embodiments shown in FIG. 8 to FIG. 22, only the main differences between the embodiments are described for the sake of brevity.

Referring to FIG. 32, the structure at this manufacturing stage is similar to the structure at the manufacturing stage shown in FIG. 12. A through hole 164 is also formed in a stack structure including a first conductive layer 160 and a sacrificial layer 162. However, each of the through holes 164 shown in FIG. 32 is a strip-shaped through hole extending along a Y-direction and overlapping more than one active area 103. A dielectric spacer 122 is disposed on the sidewall of each through holes 164 and extends along the Y-direction. A patterned second conductive layer (not shown) and a dielectric cap layer 129 are filled into the through holes 164, and form a strip-shaped structure extending along the Y-direction.

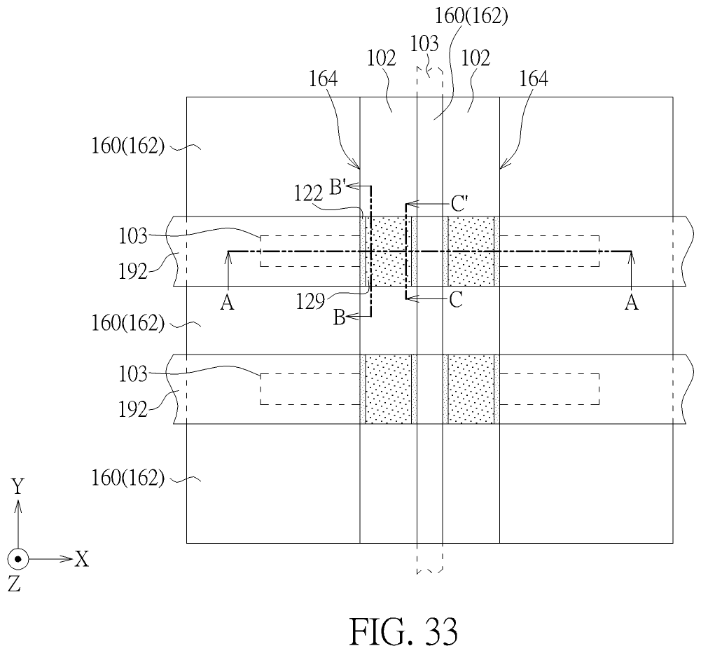

FIG. 33 is a schematic cross-sectional view at a manufacturing stage subsequent to FIG. 32 according to some embodiments of the present disclosure. Referring to FIG. 33, an etch mask 192 extending along an X-direction is formed to cover portions of the patterned second conductive layer (not shown), the dielectric cap layer 129, the first conductive layer 160 and the sacrificial layer 162. Then, an etching process is performed to remove the layers or structures not protected by the etch mask 192. Thus, the original strip-shaped structure, which contains the patterned second conductive layer and the dielectric cap layer 129 stacked in sequence, can be interrupted to thereby expose the underlying isolation structure 102.

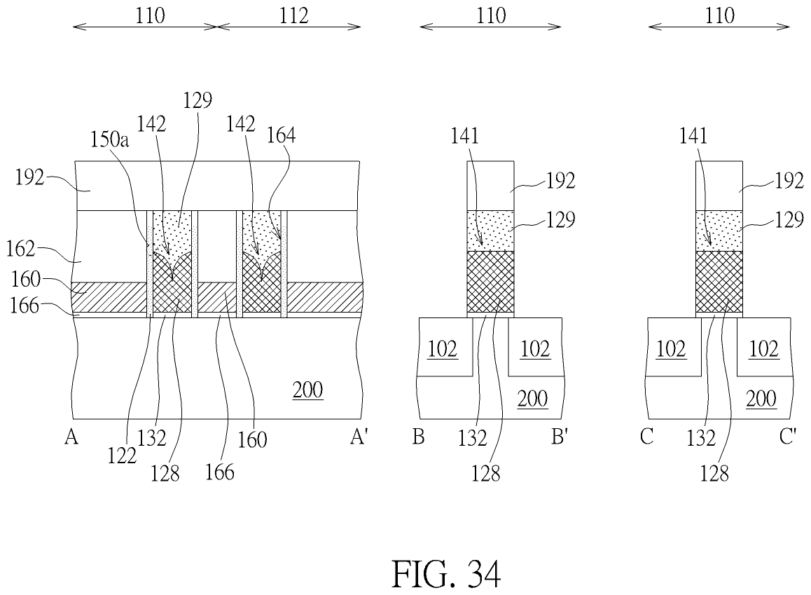

FIG. 34 is a schematic cross-sectional view of a non-volatile memory device corresponding to line A-A′, line B-B′ and line C-C′ of FIG. 33 according to some embodiments of the present disclosure.

Referring to view AA′ of FIG. 34, the etch mask 192 covers the patterned second conductive layer 128, the dielectric cap layer 129, the first conductive layer 160 and the sacrificial layer 162.

Referring to view BB′ and view CC′ of FIG. 34, the top surface 141 of the patterned second conductive layer 128 is substantially flat, and is covered with the dielectric cap layer 129 and the etch mask 192. The etch mask 192 is used to protect the underlying layers from etching during an etching process. Thus, the layers not covered with the etch mask 192 are removed when the etching process is complete, and thus the isolation structure 102 is exposed.

Afterwards, the manufacturing processes similar to those described in FIGS. 13-22 and other manufacturing processes can be performed to obtain a non-volatile memory device similar to the structure shown in FIGS. 5 and 6.

By using the non-volatile memory device according to the embodiments of the present disclosure, the electrons sorted in the floating gate can be pulled out of the floating gate more efficiently since one or more of the top edges of the floating gate, which form a parallel or closed shape as viewed from a top-down perspective, can act as a transmission path for the electrons. As a result, the required erase voltage is reduced, and the efficiency of erasing the stored data is improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A non-volatile memory device, comprising at least one memory cell, wherein the at least one memory cell comprises:
a substrate;
a select gate disposed on the substrate;
a floating gate disposed on the substrate and laterally spaced apart from the select gate, wherein the floating gate comprises a plurality of top edges forming a closed shape as viewed from a top-down perspective;
a floating gate cap layer disposed on a top surface of the floating gate, wherein an area of a top surface of the floating gate cap layer is less than an area of a bottom surface of the floating gate;
an erase gate disposed on the floating gate, wherein one or more of the plurality of top edges are covered with the erase gate; and
a control gate covered with the erase gate, wherein the floating gate is disposed between the control gate and the select gate.

2. The non-volatile memory device of claim 1, wherein the plurality of top edges of the floating gate are higher than a top surface of the select gate.

3. The non-volatile memory device of claim 1, wherein the floating gate further comprises two sidewalls disposed opposite each other, and each of the sidewalls is partially covered with the select gate.

4. The non-volatile memory device of claim 3, further comprising a dielectric spacer disposed between each of the sidewalls and the select gate.

5. The non-volatile memory device of claim 1, further comprising an inter-gate dielectric layer surrounding the floating gate as viewed from a top-down perspective, wherein a top surface of the inter-gate dielectric layer is lower than the plurality of top edges.

6. The non-volatile memory device of claim 5, wherein the inter-gate dielectric layer covers a top surface of the select gate and a top surface of the control gate.

7. The non-volatile memory device of claim 5, further comprising an erase gate dielectric layer disposed on the inter-gate dielectric layer and covering the top surface of the select gate and the top surface of the control gate.

8. The non-volatile memory device of claim 1, wherein the top surface of the floating gate further comprises a center region lower than the plurality of top edges.

9. The non-volatile memory device of claim 8, wherein the floating gate comprises a top tip surrounding the center region of the top surface of the floating gate as viewed from a top-down perspective.

10. The non-volatile memory device of claim 9, wherein a lowermost portion of the floating gate cap layer is surrounded by the top tip of the floating gate as viewed from a top-down perspective.

11. The non-volatile memory device of claim 8, wherein the plurality of top edges comprises:
two first top edges opposite each other and arranged along a first direction; and
two second top edges opposite each other and arranged along a second direction different from the first direction,
wherein the first top edges and the second top edges are higher than the center region of the top surface of the floating gate.

12. The non-volatile memory device of claim 1, wherein the at least one memory cell comprising a first memory cell and a second memory cell, each of the first memory cell and the second memory cell comprising the select gate, the floating gate and the floating gate cap layer, and the non-volatile memory device further comprises a source region and control gate shared by the first memory cell and the second memory cell, and the source region is covered with the erase gate.

13. The non-volatile memory device of claim 12, wherein the first memory cell and the second memory cell have a mirror image of each other.

14. The non-volatile memory device of claim 12, wherein the control gate is covered with the erase gate.

15. The non-volatile memory device of claim 1, wherein the top surface of the floating gate cap layer is lower than one or more of the plurality of top edges.

16. The non-volatile memory device of claim 15, wherein the top surface of the floating gate cap layer is covered with the erase gate.

17. The non-volatile memory device of claim 1, wherein all of the plurality of top edges are covered with and electrically coupled to the erase gate.

18. A method for manufacturing a non-volatile memory device, comprising:
providing a substrate;
forming a first conductive layer and a sacrificial layer on the substrate, wherein the conductive layer is disposed between the sacrificial layer and the substrate;
forming at least one through hole penetrating the first conductive layer and a sacrificial layer;
filling a second conductive layer into the at least one through hole;
etching the second conductive layer to form a patterned second conductive layer in the at least one through hole, wherein the patterned second conductive layer comprises at least one top edge;
forming a dielectric cap layer in the at least one through hole, wherein the dielectric cap layer covers a top surface of the patterned second conductive layer;
etching the sacrificial layer to expose portions of the patterned second conductive layer; and
etching the dielectric cap layer until an area of a top surface of the dielectric cap layer is less than an area of a bottom surface of the patterned second conductive layer.

19. The method for manufacturing a non-volatile memory device of claim 18, further comprising forming an isolation structure in the substrate, wherein the isolation structure comprises two opposite edges, and the at least one through hole extends beyond the opposite edges of the isolation structure.

20. The method for manufacturing a non-volatile memory device of claim 18, wherein a top surface of the patterned second conductive layer further comprises a center region higher than a bottom surface of the at least one through hole.

21. The method for manufacturing a non-volatile memory device of claim 20, wherein the center region is lower than the at least one top edges.

22. The method for manufacturing a non-volatile memory device of claim 18, before filling the second conductive layer into the at least one through hole, further comprising forming a dielectric spacer on sidewalls of the at least one through hole, wherein the dielectric spacer forms a closed shape as viewed from a top-down perspective.

23. The method for manufacturing a non-volatile memory device of claim 22, further comprising patterning the first conductive layer and the dielectric spacer.

24. The method for manufacturing a non-volatile memory device of claim 18, before etching the dielectric cap layer, further comprising:
patterning the first conductive layer to expose two opposite sidewalls of the patterned second conductive layer; and
forming a control gate dielectric layer to cover the opposite sidewalls of the patterned second conductive layer and a top surface of the dielectric cap layer; and
forming a control gate at the opposite sidewalls of the patterned second conductive layer.

25. The method for manufacturing a non-volatile memory device of claim 24, before etching the dielectric cap layer, further comprising:
forming a filling dielectric layer on the control gate, wherein a top surface of the filling dielectric layer is lower than the at least one top edge of the patterned second conductive layer.

26. The method for manufacturing a non-volatile memory device of claim 25, wherein the filling dielectric layer surrounds the patterned second conductive layer as viewed from a top-down perspective.

27. The method for manufacturing a non-volatile memory device of claim 24, after etching the dielectric cap layer, further comprising:
forming an erase gate dielectric layer to cover the least one top edge, the opposite sidewalls of the patterned second conductive layer, and the top surface of the dielectric cap layer.

28. The method for manufacturing a non-volatile memory device of claim 18, wherein the top surface of the dielectric cap layer is lower than the at least one top edge after etching the dielectric cap layer.

29. The method for manufacturing a non-volatile memory device of claim 18, wherein, before etching the sacrificial layer, the patterned second conductive layer and the dielectric cap layer form a strip-shaped structure extend along a same direction, and the method further comprises:
forming an etch mask covering portions of the patterned second conductive layer and the dielectric cap layer; and
etching the patterned second conductive layer and the dielectric cap layer exposed from the etch mask to thereby interrupt the strip-shaped structure.
